(19) United States
(12) Patent Application Publication
(10) Pub. No.: US 2024/0260230 A1
(43) Pub. Date: Aug. 1, 2024

(54) SYSTEMS AND METHODS FOR COOLING

(71) Applicant: Ferveret Inc., San Jose, CA (US)

(72) Inventors: Matteo BUCCI, Boston, MA (US); Reza AZIZIAN, San Jose, CA (US)

(21) Appl. No.: 18/405,378

(22) Filed: Jan. 5, 2024

Related U.S. Application Data
(63) Continuation of application No. PCT/US2022/036273, filed on Jul. 6, 2022.
(60) Provisional application No. 63/219,057, filed on Jul. 7, 2021.
(60) Provisional application No. 63/324,965, filed on Mar. 29, 2022.
(60) Provisional application No. 63/345,647, filed on May 25, 2022.

(51) Int. Cl. H05K 7/20

(52) U.S. Cl. CPC H05K 7/20272; H05K 7/20281; H05K 7/2029

(57) ABSTRACT

The present disclosure provides systems and method for cooling a heat source. The system may include a container comprising a container wall and a heat source, a baffle disposed between the heat source and the container wall, and one or more of a heat exchanger or recirculation loop. The heat exchanger may be a liquid-liquid heat exchanger configured to remove heat from a liquid contacting the heat source. The recirculation loop may be configured to flow a liquid contacting the heat source to cool the heat source. Methods may use the systems described herein to cool a heat source.

### CROSS-REFERENCE

This application is a continuation of U.S. International Patent Application No. PCT/US2022/036273, filed Jul. 6, 2022, which claims the benefit of U.S. Provisional Patent Application No. 63/219,057, filed Jul. 7, 2021, U.S. Provisional Patent Application No. 63/324,965, filed Mar. 29, 2022, and U.S. Provisional Patent Application No. 63/345,647, filed May 25, 2022, each of which is entirely incorporated herein by reference.

### BACKGROUND

Increases in computational demand and performance may lead to an increase in heat generation from computational systems. Thermal regulation of electronic systems may be critical for maintaining performance and longevity of electronic systems. Thus, improvements in thermal regulation and heat dissipation for electronic systems may in turn reduce costs for and increase efficiency of electronics cooling.

Electrical fault may cause unplanned downtime and shorten the lifespans of electrical components coupled with electrical networks. When electrical components operate at a temperature greater than the temperature limits of the electrical components, it may shorten the lifespans of the electrical components significantly.

When applying reactive maintenance, no action is taken until an electrical fault is detected. This may compromise the lifespans of electrical components of a system, and result in unexpected downtime and expensive maintenance. In contrast, when applying preventive maintenance, hours of operation, time elapsed since the last maintenance, and the like, are taken into consideration. A preventive maintenance can be triggered periodically to prevent an electrical fault. However, existing preventive maintenance mechanisms may not consider the actual, real-time conditions of the electrical components, which may lead to maintenances that are performed earlier than needed. This may result in excessive maintenances that are not cost-efficient. In some instances, preventive maintenance may be scheduled at a timepoint that is too late if some components of the electrical networks fail unexpectedly and prematurely.

### SUMMARY

Provided herein are systems and methods that may be useful for cooling one or more components of various electronic systems. The systems and methods described herein may permit cooling of electronic components, such as computer servers, with increased efficiency and improved functionality as compared to other systems for electronic cooling.

The predictive maintenance mechanism described herein can monitor real-time conditions of the electrical components, electrical cords, and other components coupled with electrical networks. The predictive maintenance herein can be triggered by the monitored status of electrical networks to perform corrective actions, which aids in extending the lifetime of the system without experiencing critical failures and downtime.

Individual electrical component on the same electrical network can affect each other's status due to the flow of electric current, heat generated, electromagnetic field effects, vibration and noise, etc. Additionally, switches within a network may change the topological relationships between electrical components at any given moment. Therefore, applying a pre-determined set of rules may not be optimal for detecting and predicting electrical faults, due to the dynamic nature of electrical networks.

As described herein, Intelligent algorithms (e.g., Artificial Intelligence, Machine Learning, etc.) may be utilized to simulate an electrical network environment to provide solutions for predictive maintenance based on real-time condition monitoring data. A variety of sensors may be installed on the electrical network to provide real-time condition monitoring data to one or more of the intelligent algorithms. Continuous measurements of real-time condition data provided to the intelligent algorithms can allow simulation of the electrical network monitored and generate actionable insights regarding the health of the electrical network and individual electrical component associated with the electrical network.

The passage of electric current through an electrical component generates heat. Continuous measurements and monitoring of temperature associated with the electrical components can provide another set of data that may be utilized by the intelligent algorithms to predict the probability and remaining time to the next expected electrical fault, and thereby facilitate early corrective actions.

In an aspect, the present disclosure provides a cooling system, comprising: a container comprising a container wall, wherein the container is configured to retain a heat source submerged in a first liquid, wherein, during use, the first liquid is in thermal communication with the heat source and is configured to remove thermal energy from the heat source; a baffle in the container, wherein, during use, the baffle is disposed between the heat source and the container wall andis configured to direct flow of the first liquid during transfer of thermal energy away from the heat source; and a heat exchanger disposed in the container, wherein, during use, the heat exchanger is in thermal communication with and fully submerged in the first liquid and is configured to flow a second liquid configured to remove thermal energy from the first liquid to thereby cool the heat source.

In another aspect, the present disclosure provides a cooling system, comprising: a container comprising a container wall, wherein the container comprises a heat source submerged in a first liquid, wherein the first liquid is in thermal communication with the heat source and is configured to remove thermal energy from the heat source; a baffle disposed between the heat source and the container wall, wherein the baffle is configured to direct flow of the first liquid during transfer of thermal energy away from the heat source; and a heat exchanger in thermal communication with and fully submerged in the first liquid, wherein the heat exchanger is configured to flow a second liquid configured to remove thermal energy from the first liquid to thereby cool the heat source.

In some embodiments, the heat exchanger is disposed between the baffle and the container wall. In some embodiments, the cooling system further comprises an additional container comprising the heat exchanger, wherein the additional container is in fluid communication with the container such that, during use, the first liquid flows between the container and the additional container. In some embodiments, the heat exchanger comprises a plurality of tubes configured to flow the second liquid. In some embodiments, the cooling system further comprises a blower configured to cool at least a portion of the first liquid. In some embodiments, the baffle is configured to direct flow of the first liquid towards the heat exchanger. In some embodiments, the first liquid is maintained separate from the second liquid such that the first liquid does not contact the second liquid. In some embodiments, the first liquid is a dielectric liquid. In some embodiments, the first liquid directly contacts the heat source.

In some embodiments, the cooling system further comprises a recirculation loop configured to provide forced convection of the first liquid. In some embodiments, the baffle supports the heat source. In some embodiments, the baffle comprises a bottom plate comprising perforations configured to permit flow of the first liquid through the bottom plate. In some embodiments, the baffle comprises a baffle wall, and wherein the baffle wall comprises perforations configured to permit flow of the first liquid through the baffle wall. In some embodiments, the baffle comprises a flow diverter configured to direct flow of the first liquid around the heat source.

In some embodiments, the system further comprises a lid configured to seal the container. In some embodiments, the system further comprises a liquid lid disposed adjacent to and above the first fluid, wherein the liquid lid is configured to seal the container. In some embodiments, the system may further comprise a float configured to reduce a volume of the liquid lid. In some embodiments, the container comprises a relief valve configured to maintain a pressure of the container below a threshold value. In some embodiments, the system further comprises a liner configured to seal the first liquid inside the container. In some embodiments, the liner is a rigid liner. In some embodiments, the liner is a deformable liner. In some embodiments, the cooling system further comprises one or more processors coupled to the heat exchanger, wherein the one or more processors are configured to regulate flow of the second liquid through the heat exchanger. In some embodiments, the cooling system further comprises a cable outlet configured to permit a portion of a cable to be disposed internal to the container and another portion of the cable to be disposed external to the container, wherein the cable outlet is configured to seal the container. In some embodiments, the cable outlet comprises a conduit comprising at least a portion of the cable and a third liquid configured to seal the cable outlet. In some embodiments, the cooling system further comprises a displacement volume configured to reduce a volume of the first liquid as compared to a system without the displacement volume. In some embodiments, the cooling system may be integrated with a renewable energy source. In some embodiments, the heat source is a mining machine. In some embodiments, the mining machine includes a wireless handle. In some embodiments, the wireless handle comprises a wireless emitter.

In another aspect, the present disclosure provides a cooling system, comprising: a container comprising a container wall, wherein the container is configured to retain a heat source submerged in a first liquid, wherein, during use, the first liquid is in thermal communication with the heat source and is configured to remove thermal energy from the heat source; a baffle in the container, wherein, during use, the baffle is disposed between the heat source and the container wall and is configured to direct flow of the first liquid during transfer of thermal energy away from the heat source; and a recirculation loop configured to flow the first liquid, wherein the recirculation loop comprises (i) a passageway comprising a converging structure and (ii) a pump configured to direct the first liquid through the converging structure of the passageway, wherein, during use, the passageway is disposed between the baffle and the container wall and the pump directs the first liquid through the converging structure to generate a suction force that pulls the first liquid through the converging structure to generate flow of the first liquid between the baffle and the container wall to thereby cool the heat source.

In another aspect, the present disclosure provides a cooling system, comprising: a container comprising a container wall, wherein the container comprises a heat source submerged in a first liquid, wherein the first liquid is in thermal communication with the heat source and is configured to remove thermal energy from the heat source; a baffle disposed between the heat source and the container wall, wherein the baffle is configured to direct flow of the first liquid during transfer of thermal energy away from the heat source; and a recirculation loop configured to flow the first liquid, wherein the recirculation loop comprises (i) a passageway comprising a converging structure disposed between the baffle and the container wall and (ii) a pump configured to direct the first liquid through the converging structure of the passageway to generate a suction force that pulls the first liquid through the converging structure to generate flow of the first liquid between the baffle and the container wall to thereby cool the heat source.

In some embodiments, the baffle is configured to direct flow of the first liquid towards the container wall. In some embodiments, the cooling system further comprises a blower configured to cool at least a portion of the first liquid. In some embodiments, the first liquid is a dielectric liquid. In some embodiments, the first liquid directly contacts the heat source. In some embodiments, the cooling system further comprises one or more processors coupled to the recirculation loop, wherein the one or more processors is configured to regulate a flow of the first liquid through the recirculation loop. In some embodiments, the baffle supports the heat source. In some embodiments, the baffle comprises a bottom plate comprising perforations configured to permit flow of the first liquid through the bottom plate. In some embodiments, the baffle comprises a baffle wall, and wherein the baffle wall comprise perforations configured to permit flow of the first liquid through the baffle wall. In some embodiments, the baffle comprises a flow diverter configured to direct flow of the first liquid around the heat source.

In some embodiments, the cooling system further comprises a lid configured to seal the container. In some embodiments, the system further comprises a liquid lid disposed adjacent to and above the first fluid, wherein the liquid lid is configured to seal the container. In some embodiments, the system may further comprise a float configured to reduce a volume of the liquid lid. In some embodiments, the container comprises a relief valve configured to maintain a pressure of the container below a threshold value. In some embodiments, the cooling system further comprises a liner configured to seal the first liquid inside the container. In some embodiments, the liner is a rigid liner. In some embodiments, the liner is a deformable liner. In some embodiments, the cooling system further comprises a cable outlet configured to permit a portion of a cable to be disposed internal to the container and another portion of the cable to be disposed external to the container, wherein the cable outlet is configured to seal the container. In some embodiments, the cable outlet comprises a conduit comprising at least a portion of the cable and a third liquid configured to seal the cable outlet. In some embodiments, the cooling system further comprises a displacement volume configured to reduce a volume of the first liquid as compared to a system without the displacement volume. In some embodiments, the cooling system may be integrated with a renewable energy source. In some embodiments, the heat source is a mining machine. In some embodiments, the mining machine includes a wireless handle. In some embodiments, the wireless handle comprises a wireless emitter.

In another aspect, the present disclosure provides a method for cooling a heat source, comprising: (a) providing a cooling system in thermal communication with the heat source, wherein the cooling system comprises (i) a container comprising a container wall, wherein the container comprises the heat source submerged in a first liquid, (ii) a baffle disposed between the heat source and the container wall, and (iii) a heat exchanger in thermal communication with and fully submerged in the first liquid, wherein the first liquid is in thermal communication with the heat source; (b) transferring thermal energy from the heat source to the first liquid and, during the transferring, using the baffles to direct flow of the first liquid away from the heat source; and (c) using the heat exchanger to flow a second liquid, wherein the second liquid removes thermal energy from the first liquid to thereby cool the heat source.

In some embodiments, the method further comprises flowing the first liquid to maintain the first liquid in a subcooled state. In some embodiments, the heat exchanger is disposed between the baffle and the container wall. In some embodiments, the method further comprises flowing the first liquid to an additional container in fluid communication with the container, wherein the heat exchanger is disposed in the additional container. In some embodiments, the heat exchanger comprises a plurality of tubes that flow the second liquid. In some embodiments, the method further comprises using a blower to cool at least a portion of the first liquid. In some embodiments, the baffle directs the first liquid towards the heat exchanger. In some embodiments, the method further comprises using a pump coupled to the heat exchanger, wherein the pump directs the second liquid to flow through the heat exchanger. In some embodiments, the method further comprises using one or more processors coupled to the pump to control a flow rate of the second liquid through the heat exchanger.

In some embodiments, the first liquid is a dielectric liquid. In some embodiments, the first liquid directly contacts the heat source. In some embodiments, the baffle supports the heat source. In some embodiments, the baffle comprises a bottom plate comprising perforations that permit flow of the first liquid through the bottom plate. In some embodiments, the baffle comprises a baffle wall, and wherein the baffle wall comprises perforations that permit flow of the first liquid through the baffle wall. In some embodiments, the baffle comprises a flow diverter that directs flow of the first liquid around the heat source.

In some embodiments, the container comprises a lid that seals the container. In some embodiments, the cooling system comprises a liquid lid disposed adjacent to and above the first liquid. In some embodiments, the system further comprises a float configured to reduce a volume of the liquid lid. In some embodiments, the container comprises a relief valve that maintains a pressure of the container below a threshold value. In some embodiments, the container comprises a liner that seals the first liquid inside the container. In some embodiments, the liner is a rigid liner. In some embodiments, the liner is a deformable liner. In some embodiments, the method further comprises integrating the cooling system with a renewable energy source. In some embodiments, the method further comprises using the second liquid for secondary heating. In some embodiments, the heat source is a mining machine. In some embodiments, the mining machine comprises a wireless handle. In some embodiments, the wireless handle comprises a wireless emitter.

In another aspect, the present disclosure provides a method for cooling a heat source, comprising: (a) providing a cooling system in thermal communication with the heat source, wherein the cooling system comprises (i) a container comprising a container wall, wherein the container comprises the heat source submerged in a first liquid, (ii) a baffle disposed between the heat source and the container wall, and (iii) a recirculation loop comprising (A) a passageway comprising a converging structure disposed between the baffle and the container wall and (B) a pump that directs the flow of the first liquid through the converging structure, wherein the first liquid is in thermal communication with the heat source; (b) transferring thermal energy from the heat source to the first liquid and, during the transferring, using the baffles to direct flow of the first liquid away from the heat source; and (c) using the pump of the recirculation loop to direct the first liquid through the converging structure of the passageway to generate a suction force that pulls the first liquid through the converging structure and generates flow of the first liquid between the baffle and the container wall to thereby cool the heat source.

In some embodiments, the method further comprises flowing the first liquid such that the first liquid is maintained in a subcooled state. In some embodiments, the baffle directs the first liquid towards the container wall. In some embodiments, the first liquid is a dielectric liquid. In some embodiments, the first liquid directly contacts the heat source. In some embodiments, the method further comprises using a blower to cool at least a portion of the first liquid.

In some embodiments, the baffle supports the heat source. In some embodiments, the baffle comprises a bottom plate comprising perforations that permit flow of the first liquid through the bottom plate. In some embodiments, the baffle comprises a baffle wall, and wherein the baffle wall comprises perforations that permit flow of the first liquid through the baffle wall. In some embodiments, the baffle comprises a flow diverter that directs flow of the first liquid around the heat source.

In some embodiments, the container comprises a lid that seals the container. In some embodiments, the cooling system comprises a liquid lid disposed adjacent to and above the first liquid. In some embodiments, the system further comprises a float configured to reduce a volume of the liquid lid. In some embodiments, the container comprises a relief valve that maintains a pressure of the container below a threshold value. In some embodiments, the container comprises a liner configured to seal the first liquid inside the container. In some embodiments, the liner is a rigid liner. In some embodiments, the liner is a deformable liner. In some embodiments, the method further comprises using one or more processors coupled to the pump to control a flow of the first liquid through the converging structure. In some embodiments, the method further comprises integrating the cooling system with a renewable energy source. In some embodiments, the method further comprises using the first liquid for secondary heating. In some embodiments, the heat source is a mining machine. In some embodiments, the mining machine comprises a wireless handle. In some embodiments, the wireless handle comprises a wireless emitter.

In another aspect, the present disclosure provides a kit comprising the cooling system described herein and a single container comprising the first liquid and a liquid lid. In some embodiments, the first liquid and the liquid lid are configured to phase separate upon addition to the cooling system.

In another aspect, the present disclosure provides a method for predicting an overheating even to aid in cooling a heat source, the method comprising (a) receiving a plurality of parameters associated with a plurality of electrical components of an electrical network from a plurality of sensors, wherein one of said plurality of sensors is a temperature sensor; and (b) computer processing the plurality of parameters with a predictive model to generate an output indicative of the overheating event, wherein the predictive model is trained on a training dataset comprising a plurality of historical data of the plurality of parameters across different time points, and wherein the plurality of historical data is labeled as originating or not originating from an electrical component that has undergone an overheating event.

In some embodiments, the predictive model is a binary predictive model, and wherein the output is a binary output that indicates whether one of the plurality of electrical components will or will not have said overheat event. In some embodiments, the predictive model is a multi-class predictive model, and wherein the output comprises a probability distribution over a plurality of levels or imminency of said overheat event. In some embodiments, the plurality of sensors comprises electrical characteristic sensors. In some embodiments, the training dataset comprises a plurality of historical data on thermal measurements received from the temperature sensor and electrical characteristic measurements from the electrical characteristic sensors. In some embodiments, the training dataset comprises topological relationships between the plurality of electrical components. In some embodiments, the temperature sensor is an infrared thermometer.

The systems and methods described above can provide accurate real-time condition monitoring of an electrical network, predict upcoming failures and overheat events, and prompt timely correction actions. The systems and methods herein can improve the overall efficiency of the electrical network and the lifespans of electrical components and reduce unplanned downtime of the system thereby resulting in lower operating costs. The owners of the facilities can receive early warnings of the general health of the electrical networks and can make informed decisions based on the prediction of electrical failures and overheat events.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “figure” and “FIG.” herein), of which:

FIG. 1 schematically illustrates an example cooling system with internal liquid-liquid heat exchanger;

FIG. 2 schematically illustrates an example cooling system with external liquid-liquid heat exchanger;

FIG. 3 schematically illustrates an example cooling system with blower;

FIGS. 4A-4D schematically illustrate example baffle configurations; FIG. 4A schematically illustrates an example baffle structure with open bottom; FIG. 4B schematically illustrates an example baffle structure with perforated bottom; FIG. 4C schematically illustrates an example baffle structure with perforated baffle walls; FIG. 4D schematically illustrates an example baffle structure with flow diverter;

FIG. 5 schematically illustrates an example container with a rigid liner and an example container with a deformable liner;

FIG. 6 schematically illustrates example liquid displacement volumes;

FIG. 7 schematically illustrates an example cooling system with cable outlet;

FIG. 8 schematically illustrates an example single-phase cooling system;

FIG. 9 schematically illustrates an example single-phase cooling system using forced convection conditions;

FIG. 10 schematically illustrates an example two-phase cooling system;

FIG. 11 schematically illustrates an example two-phase cooling system using forced convection conditions;

FIG. 12 illustrates a block diagram depicting an example system comprising a client-server architecture and network configured to perform the various methods described herein;

FIG. 13 illustrates a flow diagram depicting an example process for intelligently cooling a computational system, according to one embodiment;

FIG. 14 illustrates a flow diagram depicting an example process for intelligently cooling a computational system, according to one embodiment;

FIG. 15 shows a computer system that is programmed or otherwise configured to implement methods provided herein;

FIG. 16 shows an example cooling system without a lid;

FIG. 17 shows an example cooling system including a gas tight lid;

FIG. 18 shows an example dielectric fluid covered by an immiscible liquid lid;

FIG. 19 shows an example cooling system including a liquid lid;

FIG. 20 shows another example cooling system including a liquid lid;

FIG. 21 shows an example simplified cooling system including a liquid lid;

FIG. 22 shows an example cooling system including a liquid lid and float;

FIG. 23 shows an example wireless handle for a heat source;

FIGS. 24A-24D show multiple views of an example wireless handle; FIG. 24A shows a side view of an example wireless handle; FIG. 24B shows a front view of an example wireless handle; FIG. 24C shows a lateral view of an example wireless handle; FIG. 24D shows a perspective view of an example wireless handle;

FIG. 25 shows an example heat source comprising cables (e.g., network cables);

FIG. 26 shows an example heat source integrated with a wireless handle; and

FIG. 27 shows an example system integrating a cooling system with a renewable energy source for energy storage.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

The term “heat source” as used herein, generally refers to any component that generates heat and may benefit from dissipation of the heat or cooling. A heat source may be an electronic component. The electronic component may be a computer server, battery, personal computer, or other electronic component. The heat source may include a single electronic component or a plurality of electronic components.

The term “baffle” as used herein, generally refers to a structure configured to restrain, regulate, or direct flow of a fluid, such as a liquid or a gas. A baffle may include one or more of walls, a bottom plate, a top plate, or any combination thereof. A baffle may additionally include further flow diverting or regulating features such as, for example, perforations, flow diverts, flow restrainer plugs, or any combination thereof.

The term “dielectric liquid” as used here, generally refers to a dielectric material in a liquid state. A dielectric liquid may prevent or rapidly quench electric discharges. A dielectric liquid may be used as an electrical insulator and may prevent electrical communication between electronic components.

The term “recirculation loop” as used herein generally refers to a structure or feature that generates movement of a fluid (e.g., liquid or gas) within the system. A recirculation loop may pull fluid from one portion of a system and direct the fluid to another portion of the system. A recirculation loop may include piping, pumps, structures for directing fluid flow, or any combination thereof. A recirculation loop may be disposed inside a container comprising a heat source. Alternatively, or in addition to, a recirculation loop may be disposed external to a container comprising a heat source.

The term “flow diverter” as used herein generally refers to a structure configured to divert or direct flow of a fluid (e.g., liquid or gas) in the system. A flow diverter may include conduits, piping, converging or diverging structures, or other structures that divert, control, or direct flow of a fluid. A flow diverter may be standalone structures or may be coupled to or integrated with ancillary structures (e.g., baffles, recirculation loops, etc.) within the system.

The term “displacement volume” as used herein, generally refers to a volume added to a container to displace a volume of fluid. For example, a container may be configured to hold or retainer a number of heat sources (e.g., computer servers). The container may include a number of slots, each slot configured to hold a heat source. In an example, not all of the slots are filled by heat sources and additional liquid may be used to fill the container. Alternatively, a displacement volume may be used to displace the liquid such that additional liquid is not added to fill the container. The displacement volume may reduce the amount of liquid used for cooling, increase efficiency of the system by avoiding diversion of liquid into empty slots or regions of the container, or any combination thereof. A displacement volume may be a structure filled with air, liquid, solid material, or any combination thereof.

The term “liquid lid” as used herein, generally refers to an immiscible fluid floating on or disposed above another liquid (e.g., first liquid). The liquid lid may span an opening of the tank of the cooling system. The liquid lid may comprise a non-volatile fluid. The liquid lid may be configured to prevent or reduce or may prevent or reduce evaporation of the first liquid (e.g., cooling liquid). The liquid lid may permit cables, wires, or other components to pass from the tank of the cooling system to an external environment while preventing evaporation of the first liquid (e.g., cooling liquid). The liquid lid may include at least one, two, three, four, five, six, seven, eight, nine, ten, or more layers of different non-volatile fluids.

### Systems for Cooling a Heat Source

In an aspect, the present disclosure provides a cooling system comprising a container, a baffle, and a heat exchanger. The container may comprise a container wall, a heat source, and a first liquid. The heat source may be disposed in or submerged in the first liquid. The first liquid may be configured to remove or may remove thermal energy from the heat source. The baffle may be disposed between the heat source and the container wall. The baffle may be configured to direct flow of the first liquid or may direct flow of the first liquid during transfer of thermal energy away from the heat source. The heat exchanger may be in thermal communication with the first liquid. The heat exchanger may be fully submerged in the first liquid. The heat exchanger may be configured to flow or may flow a second liquid. The second liquid may be configured to remove or may remove thermal energy from the first liquid to thereby cool the heat source.

In another aspect, the present disclosure provides a cooling system comprising a container, a baffle, and a recirculation loop. The container may include a container wall, a heat source and a first liquid. The heat source may be disposed in or submerged in the first liquid. The first liquid may be configured to remove or may remove thermal energy from the heat source. The baffle may be disposed between the heat source and the container wall. The baffle may be configured to direct flow of or may direct flow of the first liquid during transfer of thermal energy away from the heat source. The recirculation loop may be configured to flow or may flow the first liquid. The recirculation loop may include a passageway and a pump. The passageway may comprise a converging structure and may be disposed between the baffle and the container wall. The pump may be configured to direct or may direct the first liquid through the converging structure of the passageway to generate a suction force that pulls the first liquid through the converging structure. The suction force may generate flow of the first liquid between the baffle and the container wall to cool the heat source.

The system may be configured to permit or may permit single-phase or two-phase heat transfer. The system may be configured to permit or may permit natural circulation of the first liquid (e.g., due to natural convection of the first liquid), forced circulation, or a combination of natural and forced circulation to cool the heat source. The system may be used to cool a heat source. The heat source may comprise a heat generating electronic component (e.g., central processing unit). Alternatively, or in addition to, the heat source may be a non-electronic component. The heat source may be disposed within the baffle structure. The heat source may be a single electronic component or may be multiple electronic components. The electronic component(s) may include, but are not limited to, central processing units (CPUs), graphics processing units (GPUs), circuit boards, chipsets, memory drivers, batteries, or any combination thereof. Electronic components may be used for any application, including, but not limited to, data storage, computer processing, electronic currency mining, or any combination thereof. In an example, the heat source includes a plurality of computer servers. The heat source may include at least 1, 2, 3, 4, 5, 6, 8, 10, 12, 15, 20, 40, 60, 80, 100, or more computer servers. The container may be configured to hold a number of rack units (U). In an example, a rack unit may be a height of a rack frame. A rack frame may have a dimension of about 19 inches by 23 inches by 1 inch rack unit (U). A rack unit may be 1.75 inches or 4.4 centimeters. In an example, the container may be configured to hold and cool greater than or equal to about 1 U, 2 U, 3 U, 4 U, 5 U, 6 U, 8 U, 10 U, 12 U, 15 U, 20 U, 30 U, 40 U, 60 U, 80 U, 100 U, or more. In an example, a container is configured to hold and cool greater than or equal to 96 U. The heat source may be submerged or immersed in the first liquid. The heat source may be fully or completely submerged in the heat source.

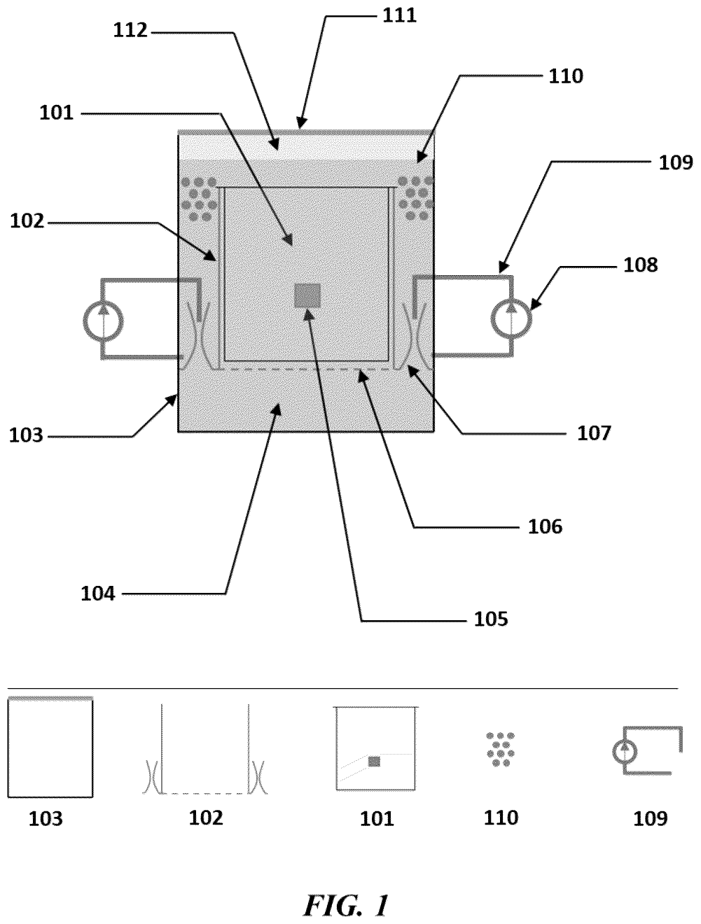

FIG. 1 schematically illustrates an example cooling system. The system may include a heat source 101 (e.g., computer server) disposed in a container 103. The system may further include a baffle 102 disposed in the container 103. The baffle 102 may be disposed between the heat source 101 and a wall of the container 103. The baffle 102 may be configured to support or may support the heat source 101. For example, the heat source 101 may include an overhang or lip that rests against a top surface of the baffle 102 to support the heat source 101. The container 103 may include a first liquid 104. The first liquid 104 may be a dielectric liquid. The heat source may include one or more heat generating components 105. The heat generating components 105 may be electronic components. The baffle 102 may include an open bottom or a bottom plate 106. In an example, the baffle 102 includes a bottom plate 106 with perforations. The baffle 102 may further include a static suction pump. The static suction pump may include a converging structure 107 that generates a suction force as the first liquid 104 flows through the converging structure 107. The converging structure 107 may be coupled to a recirculation loop 109. The recirculation loop 109 may include a pump 108. The pump 108 may be a variable speed pump. In some embodiments, the speed of the pump 108 may be controlled by commands sent from a remote platform. The cooling system may further include a heat exchanger 110. The heat exchanger 110 may include heat exchanger tubes that flow a second fluid. The container 103 may further include a lid 111 that seals the container 103. The container 103 may include a headspace 112 above the first liquid 104. The headspace 112 may comprise air.

The system may include a container. The container may be sealed to hold a liquid. Alternatively, the container may not be sealed. The container may comprise metal, plastic, wood, glass or any other material useful for forming a container. The container may comprise a single material or a combination of materials. In an example, the container comprises metal. In another example, the container comprises plastic. The container may comprise any shape, such as, for example, cubic, rectangular, or cylindrical. The container may have a first dimension (e.g., width), second dimension (e.g., length), and third dimension (e.g., height). The first dimension of the container may be greater than or equal to about 5 inches (in), 10 in, 15 in, 20 in, 30 in, 40 in, 60 in, 80 in, 100 in, 150 in, 200 in, 250 in, 300 in, 400 in, 500 in or more. The first dimension of the container may be less than or equal to about 500 in, 400 in, 300 in, 250 in, 200 in, 150 in, 100 in, 80 in, 60 in, 40 in, 30 in, 20 in, 15 in, 10 in, 5 in, or less. The second dimension of the container may be greater than or equal to about 5 in, 10 in, 15 in, 20 in, 30 in, 40 in, 60 in, 80 in, 100 in, 150 in, 200 in, 250 in, 300 in, 400 in, 500 in or more. The second dimension of the container may be less than or equal to about 500 in, 400 in, 300 in, 250 in, 200 in, 150 in, 100 in, 80 in, 60 in, 40 in, 30 in, 20 in, 15 in, 10 in, 5 in, or less. The third dimension of the container may be greater than or equal to about 5 inches (in), 10 in, 15 in, 20 in, 30 in, 40 in, 60 in, 80 in, 100 in, 150 in, 200 in, 250 in, 300 in, 400 in, 500 in or more. The third dimension of the container may be less than or equal to about 500 in, 400 in, 300 in, 250 in, 200 in, 150 in, 100 in, 80 in, 60 in, 40 in, 30 in, 20 in, 15 in, 10 in, 5 in, or less. In an example, the container may have a first dimension of greater than or equal to about 10 in, a second dimension of greater than or equal to about 30 in, and a third dimension of greater than or equal to about 20 in. In another example, the container may have a first dimension of greater than or equal to about 25 in, a second dimension of greater than or equal to about 60 in, and a third dimension of greater than or equal to about 40 in. In another example, the container may have a first dimension of greater than or equal to about 50 in, a second dimension of greater than or equal to about 120 in, and a third dimension of greater than or equal to about 80 in.

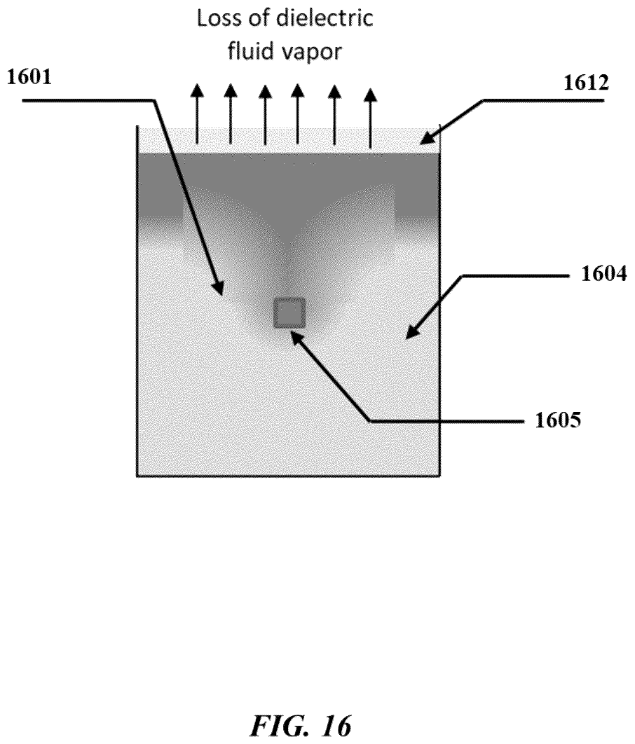

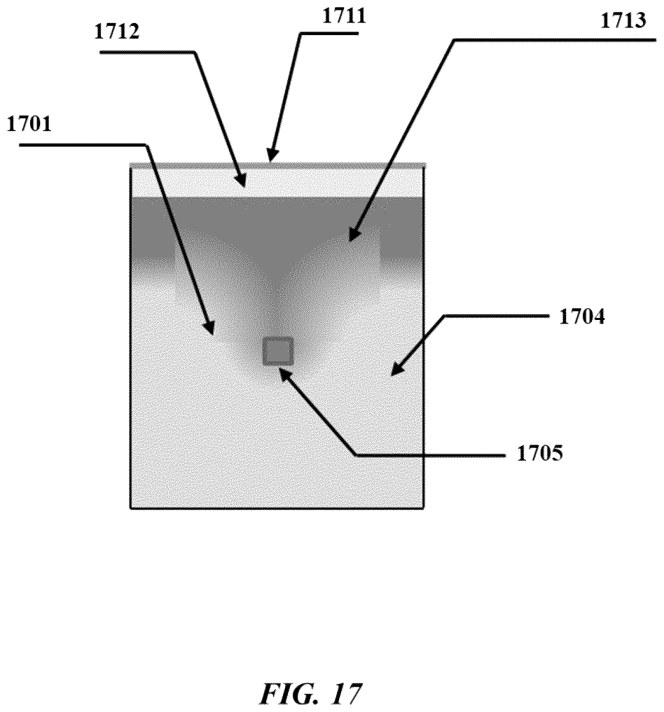

The container may include one or more of a first liquid (e.g., dielectric liquid), a baffle structure, a heat exchanger, one or more recirculation loops, or any combination thereof. The container may further include a lid. The container may include a lid or may not include a lid. The first liquid may be a volatile liquid. For example, the first liquid may be a dielectric liquid accepts thermal energy from the heat source. The thermal energy may vaporize a portion of the first liquid to generate a vapor phase of the first liquid. Vaporization of the first liquid may result in loss of the first liquid from the cooling system. FIG. 16 shows an example of an example cooling system undergoing loss of the first fluid due to lack of a lid component. The cooling system may include a computer server 1601 submerged in a fluid 1604. The computer server may include a heat generating component (e.g., CPU) 1605. Transfer of thermal energy from the heat generating component 1605 to the first liquid may cause the first liquid to vaporize and escape the cooling system through an air layer 1612 capping the first liquid. Evaporation and loss of the first liquid may increase capital costs for a cooling system. The lid may comprise a solid material (e.g., metal, plastic, wood, etc.). In an example, the lid comprises the same material as the container. The lid may provide a gas tight seal (e.g., a hermetic seal) to prevent or reduce evaporation and loss of the first liquid. FIG. 17 shows and example cooling system sealed (e.g., hermetically sealed) with a lid 1711. The cooling system may include a computer server 1701 disposed in a first fluid 1704 (e.g., dielectric). The lid 1711 may comprise a solid material (e.g., plastic, metal, etc.) disposed above the first liquid 1704 or disposed above a gaseous headspace 1712 (e.g., air) above the first fluid 1704. The first fluid 1704 may accept thermal energy from a heat source 1705. The thermal energy may cause the first liquid to undergo a phase transition to generate a vapor 1713 of the first fluid. The vapor may contact the lid 1711 and remain within the cooling system. Alternatively, or in addition to, the lid may comprise a liquid layer. The lid may be configured to seal or may seal the container. The lid may be temporarily sealed (e.g., via one or more fasteners or latches). Alternatively, the lid may be permanently sealed. For example, the lid may be sealed via an adhesive, weld, braze, or other permanent fastener. The lid may be configured to contact or may contact the first liquid. Alternatively, or in addition to, the container may include a gaseous headspace and the gaseous headspace may contact the lid. The gaseous headspace may comprise an inert gas. The inert gas may be nitrogen, argon, helium, or any other inert gas. In an example, the gaseous headspace comprises air.

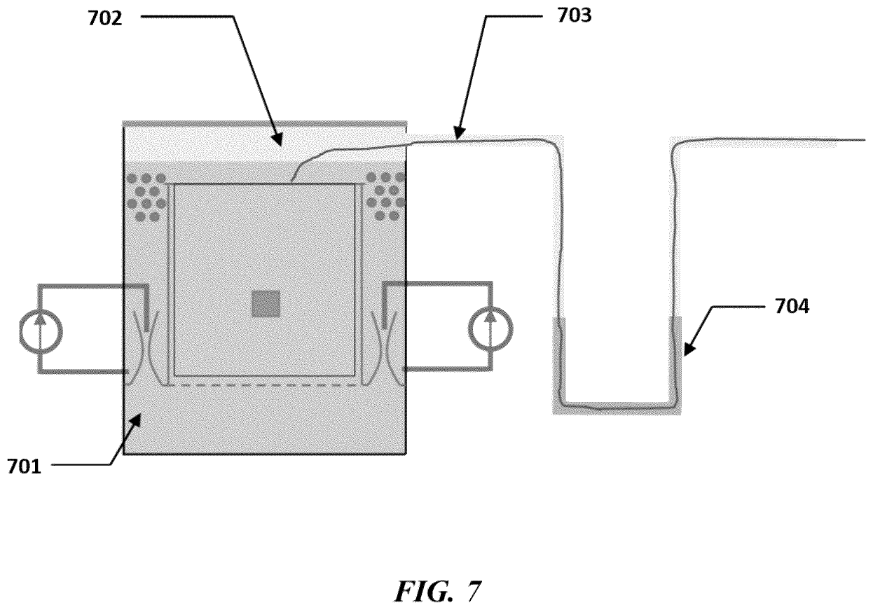

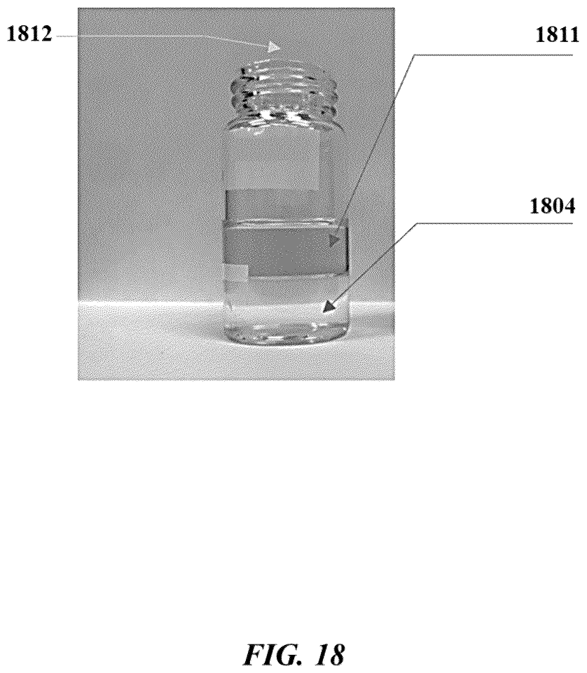

In an example, the cooling system comprises a lid. Sealing the cooling system may be challenging due to the presence of electronic cables connected to the electronic components (e.g., power cables, network cables, etc.). The cables may enter the container of the cooling system through a seal that hermetically seals the container or via a conduit comprising a third liquid configured to provide a seal around the cable, see, for example FIG. 7. Alternatively, or in addition to, the cooling system may comprise a liquid lid that seals the container. The liquid lid may provide a seal or may seal the container, may provide a seal around one or more cables, or both seal the container and provide a seal around one or more cables. FIG. 18 shows an example system comprising a first liquid 1804 (e.g., cooling liquid or dielectric liquid), a liquid lid 1811, and a headspace or air 1812 above the liquid lid. For example, the liquid lid 1811 may be sandwiched between the first liquid 1804 and the air 1812. The liquid lid may include a non-volatile or low volatility fluid. The density of the liquid lid may be less than the density of the first liquid. The density of the first liquid may be greater than or equal to about 800 kilogram per meter cubed (kg/m³), 1000 kg/m³, 1200 kg/m³, 1400 kg/m³, 1600 kg/m³, 1800 kg/m³, 2000 kg/m³, 2200 kg/m³, or greater at 25° C. The density of the first liquid may be from about 800 kg/m³ to 1000 kg/m³, 800 kg/m³ to 1200 kg/m³, 800 kg/m³ to 1400 kg/m³, 800 kg/m³ to 1600 kg/m³, 800 kg/m³ to 1800 kg/m³, 800 kg/m³ to 2000 kg/m³, 800 kg/m³ to 2200 kg/m³, 1000 kg/m³ to 1200 kg/m³, 1000 kg/m³ to 1400 kg/m³, 1000 kg/m³ to 1600 kg/m³, 1000 kg/m³ to 1800 kg/m³, 1000 kg/m³ to 2000 kg/m³, 1000 kg/m³ to 2200 kg/m³, 1200 kg/m³ to 1400 kg/m³, 1200 kg/m³ to 1400 kg/m³, 1200 kg/m³ to 1600 kg/m³, 1200 kg/m³ to 1800 kg/m³, 1200 kg/m³ to 2000 kg/m³, 1200 kg/m³ to 2200 kg/m³, 1400 kg/m³ to 1600 kg/m³, 1400 kg/m³ to 1800 kg/m³, 1400 kg/m³ to 2000 kg/m³, 1400 kg/m³ to 2200 kg/m³, 1600 kg/m³ to 1800 kg/m³, 1600 kg/m³ to 2000 kg/m³, 1600 kg/m³ to 2200 kg/m³, 1800 kg/m³ to 2000 kg/m³, 1800 kg/m³ to 2200 kg/m³, or 2000 kg/m³ to 2200 kg/m³ at 25° C. In an example, the density of the first liquid may be from about 1000 kg/m³ to 2000 kg/m³ at 25° C. The density of the liquid lid may be less than or equal to 1200 kg/m³, 1000 kg/m³, 800 kg/m³, 600 kg/m³, or less at 25° C. The density of the liquid lid may be from 600 kg/m³ to 800 kg/m³, 600 kg/m³ to 1000 kg/m³, 600 kg/m³ to 1200 kg/m³, 800 kg/m³ to 1000 kg/m³, 800 kg/m³ to 1200 kg/m³, or 1000 kg/m³ to 1200 kg/m³ at 25° C. The first liquid may have a density that is at least about 1.05, 1.1, 1.15, 1.2, 1.25, 1.3, 1.35, 1.4, 1.5, 1.6, 1.7, 1.8, 1.9, 2.0, or more times greater than liquid lid. In an example, the first liquid has a density greater than the density of the liquid lid. The liquid lid may comprise a liquid that is immiscible with the first liquid. The liquid lid may comprise an oil, water, dielectric fluid, single phase cooling fluid, or any combination thereof. The oil may include mineral oil, silicone oil, corn oil, or any other oil immiscible with the first liquid.

The liquid layer may be disposed on top of the first liquid such that the liquid lid floats on the first liquid as a discreet layer. The liquid layer may have a density that is less than the density of the first liquid such that the liquid lid forms a layer on a top surface of the first liquid (e.g., dielectric fluid). The layer of the liquid lid disposed on the top surface of the first liquid may be a continuous layer. The liquid lid may form or provide a physical barrier to prevent or reduce the release of vapor from the first liquid. The liquid layer (e.g., liquid lid) may have a thickness of greater than or equal to about 0.75 millimeters (mm), 1 mm, 1.5 mm, 2 mm, 3 mm, 4 mm, 6 mm, 8 mm, 10 mm, 15 mm, or more. The thickness of the liquid lid may be from about 0.75 mm to 1 mm, 0.75 mm to 1.5 mm, 0.75 mm to 2 mm, 0.75 mm to 3 mm, 0.75 mm to 4 mm, 0.75 mm to 6 mm, 0.75 mm to 8 mm, 0.75 mm to 10 mm, 0.75 mm to 12 mm, 1 mm to 1.5 mm, 1 mm to 2 mm, 1 mm to 3 mm, 1 mm to 4 mm, 1 mm to 4 mm, 1 mm to 6 mm, 1 mm to 8 mm, 1 mm to 10 mm, 1 mm to 12 mm, 1.5 mm to 2 mm, 1.5 mm to 3 mm, 1.5 mm to 4 mm, 1.5 mm to 6 mm, 1.5 mm to 8 mm, 1.5 mm to 10 mm, 1.5 mm to 12 mm, 2 mm to 3 mm, 2 mm to 4 mm, 2 mm to 6 mm, 2 mm to 8 mm, 2 mm to 10 mm, 2 mm to 12 mm, 3 mm to 4 mm, 3 mm to 6 mm, 3 mm to 8 mm, 3 mm to 10 mm, 3 mm to 12 mm, 4 mm to 6 mm, 4 mm to 8 mm, 4 mm to 10 mm, 4 mm to 12 mm, 6 mm to 8 mm, 6 mm to 10 mm, 6 mm to 12 mm, 8 mm to 10 mm, 8 mm to 12 mm, or 10 to 12 mm.

The liquid lid may comprise one or more different liquids. The one or more different liquids may mix to generate a single liquid composition. Alternatively, or in addition to, the liquid lid may comprise one or more different liquids that phase separate to form one or more discreet layers. The liquid lid may comprise at least one, two, three, four, five, six, seven, eight, nine, ten, or more different liquids that form a gradient of liquids with different densities. The liquid lid may comprise different liquids that generate a gradient of liquids with different densities spanning from the first liquid (e.g., dielectric liquid) to the gaseous headspace (e.g., air). For example, the liquid lid may comprise a first density adjacent to the first liquid (e.g., dielectric liquid) and a second density adjacent to the gaseous headspace (e.g., air). The first density may be greater than the second density. The first density may be at least about 1.05, 1.1, 1.15, 1.2, 1.25, 1.3, 1.35, 1.4, 1.5, 1.6, 1.7, 1.8, 1.9, 2.0, or more times greater than the second density.

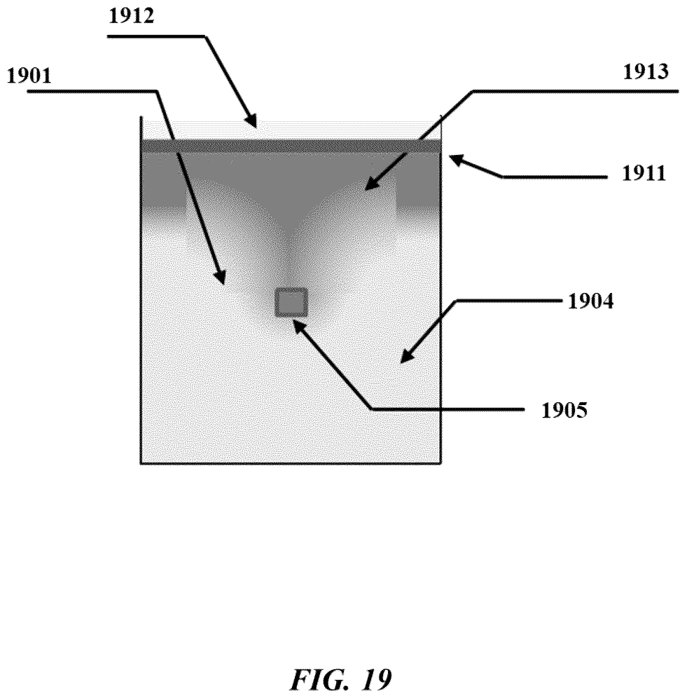

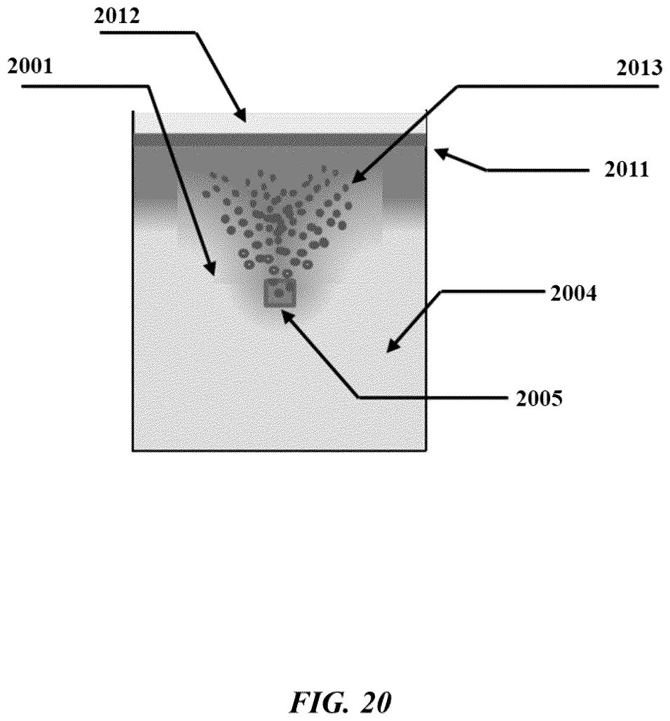

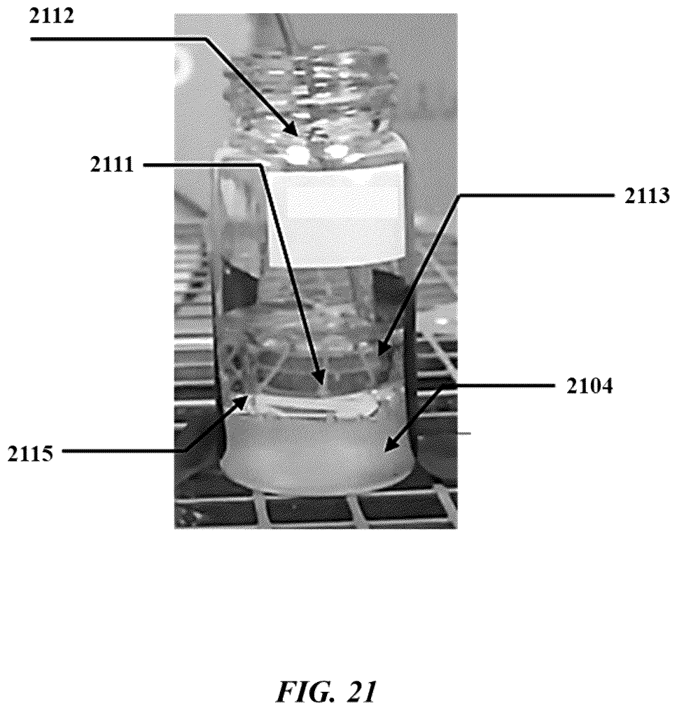

FIG. 19 shows an example cooling system comprising a liquid lid 1911. The cooling system may include an electronic component 1901 that includes a heat generating component 1905. The electronic component may be a computer server, miner machine, computing unit for artificial intelligence or autonomous driving, or any other electronic component. The computer server may be immersed or submerged in a first liquid 1904. Transfer of thermal energy from the heat source 1905 to the first liquid 1904 to generate a first fluid of lower density that moves toward the liquid lid 1911. The liquid lid 1911 may prevent first fluid from being released from the cooling system into the gaseous headspace 1912. FIG. 20 shows another example cooling system comprising a liquid lid (e.g., a lid comprising a liquid layer). In an example, the cooling system may include a computer server or other electronic component 2001 that comprises a heat source 2005. The cooling system may further include a first liquid 2004 configured to transfer thermal energy from the heat source 2005 to the first liquid 2004 and away from the heat source 2005. Transfer of thermal energy to the first liquid 2004 may cause the first liquid 2004 to undergo a phase transition and evaporate (e.g., boil) to generate bubbles 2013. The bubbles may raise through the first liquid 2004 to contact the liquid lid 2011. The liquid lid 2011 may prevent the bubbles 2013 from exiting the cooling system and contacting the gaseous headspace 2012. The bubbles 2013 may contact the liquid lid 2011 and condense or recondense in the liquid lid 2011 layer, at the interface between the first fluid 2004 and the liquid lid 2011, at the interface between the liquid lid layer 2011 and gaseous headspace 2012, or any combination thereof. The condensed first liquid 2004 may drop back into the tank of the cooling system. As such, the liquid lid 2011 may be actively cooled by the condensation of the first liquid 2004. A lid comprising a liquid layer may simplify the design of the cooling system. For example, a cooling system may include a first liquid with high-volatility (e.g., some dielectric fluids such as NOVEC™ fluids by 3M™). Hermetically sealing such a cooling system may be difficult due to the presence of cables and other electronic components disposed outside the cooling system. Using a lid comprising a liquid (e.g., liquid lid) may permit the use of a volatile first liquid without a hermetically sealed solid lid. The liquid lid may further permit cables and other electronics to protrude or extend through the liquid lid to an environment external to the tank of the cooling system without loss of a volatile first liquid. For example, and as shown in FIG. 21, the cooling system may include a first liquid 2104 with a non-volatile liquid lid 2111. The liquid lid 2111 may comprise a liquid that is immiscible with the first liquid 2104 and that is less dense than the first liquid such that it floats on top of the first liquid 2104. Upon contact with a heat source, the first liquid 2104 may undergo a phase change to generate bubbles 2113 of the first liquid. The bubbles 2113 of the first liquid 2104 may move upward towards and possibly through the liquid lid 2111. Upon contacting the liquid lid 2111, at least a portion of the bubbles 2113 may condense and move downward 2115 back towards the first liquid 2104.

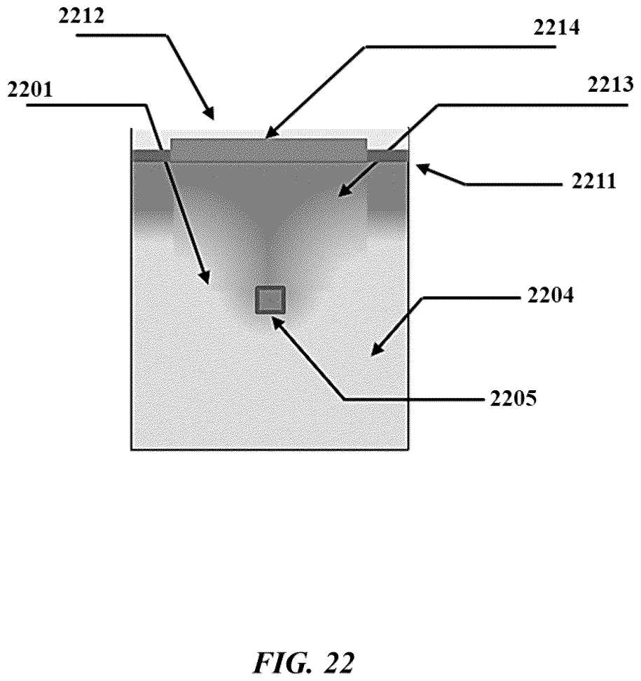

The lid of the cooling system may include a solid material (e.g., may be a metal, plastic, wood, or other solid material lid), a liquid (e.g., non-volatile liquid lid), or a combination thereof. In an example, the lid of the cooling system may include a liquid material and a solid material. The liquid portion of the lid may be as described elsewhere herein. The solid portion of the lid may include a solid floating object or a perforated floating object (e.g., such as cork or other buoyant perforated material). Alternatively, or in addition to, the solid portion of the lid may comprise multiple solid floating objects. For example, the solid portion of the lid may comprise at least one, two, three, four, five, six, seven, eight, nine, ten, or more solid floating objects. The solid floating object may comprise a metal, plastic, wood, or any combination thereof. The use of a solid floating object may permit the use a liquid lid of small volume than a cooling system without a solid floating object. The liquid lid may generate a layer continuous layer across the first liquid and the floating object may float on top of the liquid lid. Alternatively, or in addition to, the solid floating object may float on the first liquid and the liquid lid may fill any gaps between he solid floating object and the sidewalls of the tank, as shown in FIG. 22. The cooling system may include a computer server or other electronic component 2201. The computer system may include a heat generating component 2205. The cooling system may include a first liquid 2204 configured to remove thermal energy from the heat generating component 2205. Transfer of thermal energy from the heat generating component 2205 to the first liquid 2204 may generate bubbles 2213 upon evaporation of the first liquid 2204. The cooling system may further include a liquid lid 2211 and a solid floating object 2214 configured to reduce a volume of the liquid lid 2211. The solid floating object 2214 may be disposed between the first liquid 2204 and a gaseous headspace 2212. The floating object may have a density greater than, equal to, or less than a density of the liquid lid. In an example, the solid floating object has a density less than the density of the liquid lid. In an other example, the solid floating object has a density that is about equal to the density of the liquid lid. In another example, the solid floating object has a density greater than the density of the liquid lid. In another example, the solid floating object has a density between the density of the liquid lid and the density of the first liquid. The density of the solid floating object may be from about 800 kg/m³ to 1000 kg/m³, 800 kg/m³ to 1200 kg/m³, 800 kg/m³ to 1400 kg/m³, 1000 kg/m³ to 1200 kg/m³, 1000 kg/m³ to 1400 kg/m³, or 1200 kg/m³ to 1400 kg/m³ at 25° C. A ratio of the density of the solid floating object may be at least about 1.05, 1.1, 1.15, 1.2, 1.25, 1.3, 1.4, 1.5, or more times the density of the liquid lid. The density of the solid floating object may be less than 0.95, 0.9, 0.85, 0.8, 0.75, or less than the density of the first liquid.

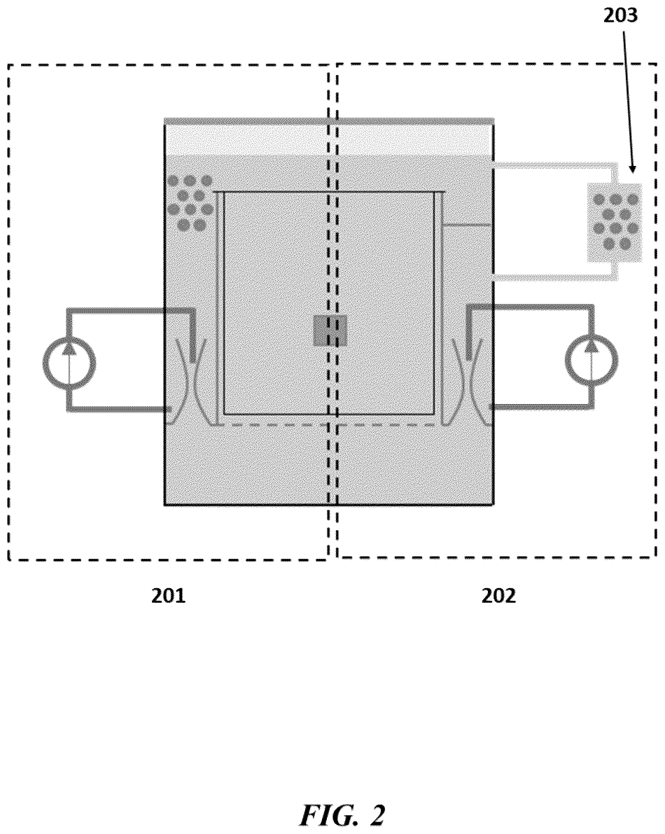

The system may include a heat exchanger or multiple heat exchangers. The system may include at least 1, 2, 3, 4, 6, 8, 10, or more heat exchangers. In an example, the system includes a single heat exchanger that spans a width of the container. In another example, the system includes at least two heat exchangers, each disposed between a baffle wall and the container wall. The heat exchanger may collect thermal energy from the first liquid, transfer the thermal energy to the second fluid, and reject the thermal energy to the external environment of the system. The heat exchanger may be disposed at or near a top of the container. The heat exchanger may be at least partially submerged in the first liquid. In an example, the heat exchanger is fully submerged in the first liquid. The heat exchanger may be disposed between the container wall and the baffle (e.g., on an outer side of the baffle). In an example, the heat exchanger is disposed above the suction pump or the converging structure of the suction pump. Alternatively, or in addition to, the heat exchanger may not be disposed in the container. For example, the heat exchanger may be disposed in an additional container that is separate from the container comprising the heat source. FIG. 2 schematically illustrates example heat exchanger configurations. In an example, the heat exchanger is disposed internal to the container 201. In another example, the heat exchanger 203 is disposed in an additional container 202. The additional container may be in fluid communication with the container via one or more pipes or tubes. The additional container may be coupled to the container by at least 2, 4, 6, 8, 10, 12, or more pipes or tubes. In an example, the additional container is coupled to the container via two tubes, one tube that directs the first liquid from the container to the additional container and another tube that directs the first liquid from the additional container back to the container. The additional container may include the heat exchanger. The heat exchanger may be fully submerged within the first liquid within the additional container. During use, the first liquid may flow between the container and the additional container.

The heat exchanger may include a plurality of tubes. The heat exchanger tubes may be the same shape or different shapes. The heat exchanger tubes may be any shape, including, but not limited to, circular, square, rectangle, or any combination thereof. The plurality of tubes may be configured to flow or may flow a second liquid. Heat exchanger may include at least 1, 2, 4, 6, 8, 10, 12, 15, 20, or more tubes. The outer side of the tubes may be in contact with the first liquid. The tube may be configured to circulate a secondary fluid. For example, an external surface of the tubes may be in contact with the first liquid and thermal energy may transfer from the first liquid, through a wall of the tube, and into the second liquid to be removed from the system. The heat exchanger may separate the first liquid from the second liquid such that the first liquid and second liquid do not contact one another.

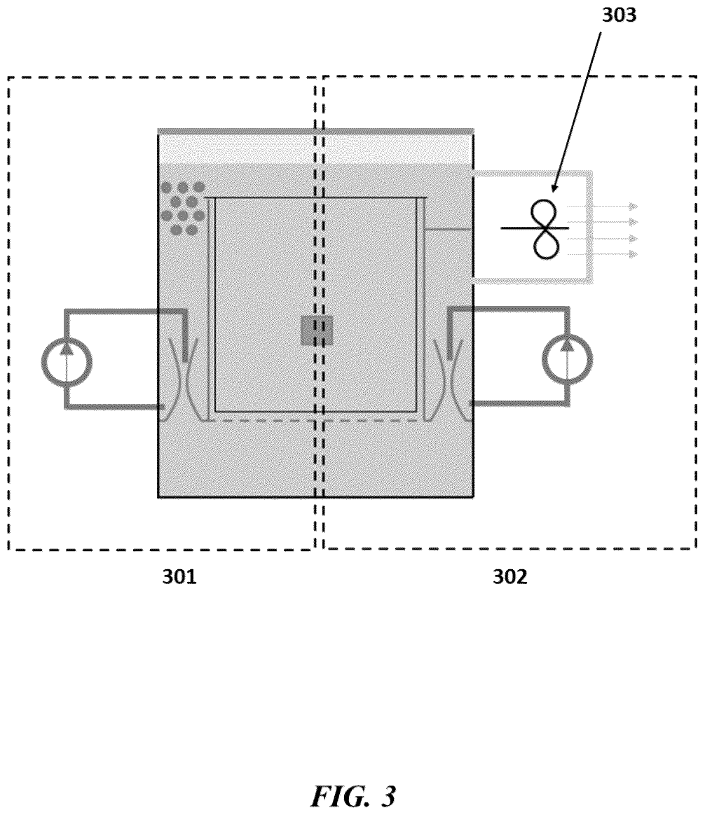

The system may further include a blower. The blower may be configured to cool or may cool a portion of the first liquid. FIG. 3 schematically illustrates an example blower configuration. The system may include a heat exchanger without a blower 301, a blower without a heat exchanger 302, or both a blower and a heat exchanger. The system may include one or more loops of piping configured to remove and circulate a portion of the first liquid. The blower 303 may be configured to pass air or may pass air across the loop of piping to remove heat from the first liquid. In some embodiments, the blower 303 may be controlled by a remote platform. The first liquid may be warmer at the top of the container than at the bottom of the container. The blower 303 may be disposed towards or near the top of the container where the fluid is higher in temperature.

The first liquid may be a coolant. The first liquid may directly contact the heat source. In an example, the first liquid is a dielectric liquid. The dielectric liquid may have high dielectric strength (e.g., be an effective dielectric), high thermal stability, be inert against components of the system, non-flammable, low toxicity, and have good heat transfer properties. In another example, the first liquid is a dielectric liquid that directly contacts the heat source. The second liquid may be a coolant. In an example, the second liquid is water. The first liquid and the second liquid may be the same liquid or may be different liquids. In an example, the first liquid and the second liquid are the same liquid. In another example, the first liquid and the second liquid are different liquids. In an example, the first liquid is a dielectric liquid and the second liquid is water. The first liquid, the second liquid, or both may comprise a dielectric liquid. The dielectric liquid may be mineral oil, hexane, heptane, castor oil, silicone oil, polychlorinated biphenyls, benzene, engineered fluids such as methoxy-nonafluorobutane or ethoxy-nonafluorobutane, or any combination thereof. The first liquid or the second liquid may comprise a coolant. The coolant may be water, deionized water, glycol, ethylene glycol, nanofluids (e.g., suspension of nanoparticles in a fluid), refrigerant, or any combination thereof. The first liquid or the second liquid may be part of a refrigeration cycle. The refrigeration cycle may include a compressor, condenser, evaporator, expansion chamber, flow metering device, or any combination thereof. The refrigeration cycle may be configured to permit or may permit the first liquid or the second liquid to reach a lower temperature and enhance cooling. For example, the second liquid and heat exchanger may be part of a refrigeration cycle to permit the second liquid to reach a temperature that is lower than an ambient temperature (e.g., lower than approximately 20° C.).

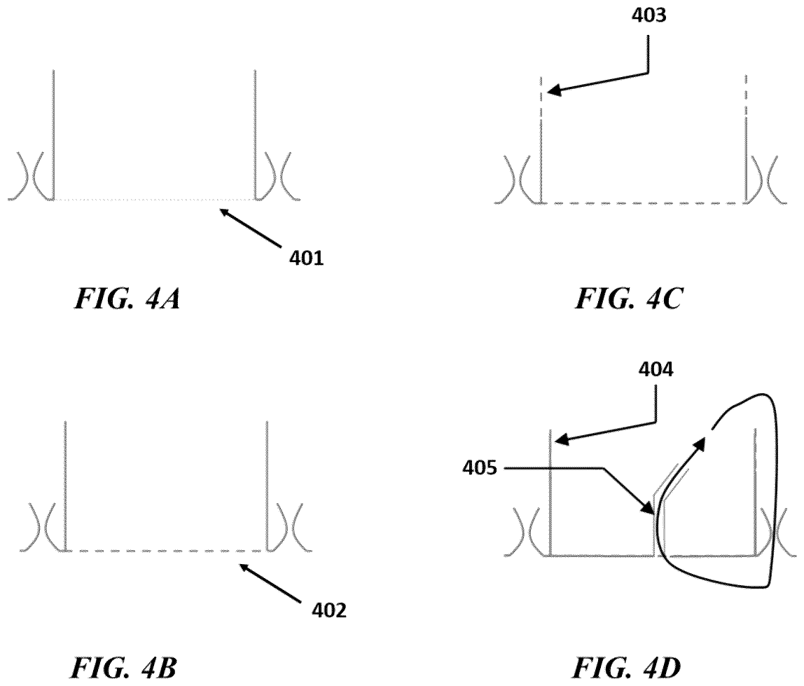

The system may further include a baffle. FIGS. 4A-4D show example baffle configurations. The heat source may be disposed within the baffle structure. For example, the baffle structure may include one or more walls and the heat source may be disposed within or between the one or more walls. The baffle may be configured to direct flow of the first liquid across the heat source and towards the heat exchanger. The baffle may support the heat source. The heat source may include a lip or overhang. The lip or overhang may be configured to rest on top of the walls of the baffle structure. The baffle structure may have an open bottom (e.g., may not include a bottom plate or other structural feature), as shown in FIG. 4A. The open bottom 401 may permit the first liquid to flow freely between the baffle walls. Alternatively, or in addition to, the baffle structure may include a bottom plate. The bottom plate may be a solid plate or may be a perforated plate, as shown in FIG. 4B. In an example, the baffle structure does not include a bottom plate. In another example, the bottom structure includes a perforated plate 402. The perforations may be configured to permit or may permit the first liquid to flow through the bottom plate. The bottom plate may have greater than or equal to 5, 10, 15, 20, 30, 40, 50, 60, 80, 100, 150, 200, 300, 500, or more perforations. The number of perforations may be dependent upon the size of the bottom plate. For example, a larger bottom plate may have a larger number of perforations. The bottom plate may comprise perforations of uniform size or the size of the perforations may vary across the bottom plate. The perforations may be circular, elliptical, square, triangular, slits, or any other shape. The perforations may have a dimension of greater than or equal to about 0.5 millimeters (mm), 1 mm, 2 mm, 3 mm, 4 mm, 5 mm, 6 mm, 8 mm, 10 mm, 15 mm, 20 mm, 30 mm, 40 mm, 50 mm, or greater. The perforations may have a dimension of less than or equal to about 50 mm, 40 mm, 30 mm, 20 mm, 15 mm, 10 mm, 8 mm, 6 mm, 5 mm, 4 mm, 3 mm, 2 mm, 1 mm, 0.5 mm, or less. The perforations may have a dimension from about 0.5 mm to 1 mm, 0.5 mm to 2 mm, 0.5 mm to 3 mm, 0.5 mm to 4 mm, 0.5 mm to 5 mm, 0.5 mm to 6 mm, 0.5 mm to 8 mm, 0.5 mm to 10 mm, 0.5 mm to 15 mm, 0.5 mm to 20 mm, 0.5 mm to 30 mm, 0.5 mm to 40 mm, 0.5 mm to 50 mm, 1 mm to 2 mm, 1 mm to 3 mm, 1 mm to 4 mm, 1 mm to 5 mm, 1 mm to 6 mm, 1 mm to 8 mm, 1 mm to 10 mm, 1 mm to 15 mm, 1 mm to 20 mm, 1 mm to 30 mm, 1 mm to 40 mm, 1 mm to 50 mm, 2 mm to 3 mm, 2 mm to 4 mm, 2 mm to 5 mm, 2 mm to 6 mm, 2 mm to 8 mm, 2 mm to 10 mm, 2 mm to 15 m, 2 mm to 20 mm, 2 mm to 30 mm, 2 mm to 40 mm, 2 mm to 50 mm, 3 mm to 4 mm, 3 mm to 5 mm, 3 mm to 6 mm, 3 mm to 8 mm, 3 mm to 10 mm, 3 mm to 15 m, 3 mm to 20 mm, 3 mm to 30 mm, 3 mm to 40 mm, 3 mm to 50 mm, 4 mm to 5 mm, 4 mm to 6 mm, 4 mm to 8 mm, 4 mm to 10 mm, 4 mm to 15 m, 4 mm to 20 mm, 4 mm to 30 mm, 4 mm to 40 mm, 4 mm to 50 mm, 5 mm to 6 mm, 5 mm to 8 mm, 5 mm to 10 mm, 5 mm to 15 m, 5 mm to 20 mm, 5 mm to 30 mm, 5 mm to 40 mm, 5 mm to 50 mm, 6 mm to 8 mm, 6 mm to 10 mm, 6 mm to 15 m, 6 mm to 20 mm, 6 mm to 30 mm, 6 mm to 40 mm, 6 mm to 50 mm, 8 mm to 10 mm, 8 mm to 15 m, 8 mm to 20 mm, 8 mm to 30 mm, 8 mm to 40 mm, 8 mm to 50 mm, 10 mm to 15 m, 10 mm to 20 mm, 10 mm to 30 mm, 10 mm to 40 mm, 10 mm to 50 mm, 15 mm to 20 mm, 15 mm to 30 mm, 15 mm to 40 mm, 15 mm to 50 mm, 20 mm to 30 mm, 20 mm to 40 mm, 20 mm to 50 mm, 30 mm to 40 mm, 30 mm to 50 mm, or 40 mm to 50 mm. The perforations in the bottom plate may be open holes. Alternatively, or in addition to, some or all of the perforations may include flow restrainer plugs. A flow restrainer plug may partially or fully block a perforation. The location of the flow restrainer plugs may be used to optimize the flow distribution of the first liquid for select heat source (e.g., server) configurations (e.g., the position or size of the heat generating components).

The baffle may include a baffle wall, as shown in FIG. 4C. The baffle wall may include perforations 403 configured to permit or that permit the first liquid to flow through the baffle wall. The perforations may be disposed across an entire dimension of the baffle wall. Alternatively, the baffle wall may include perforations disposed in an upper portion of the baffle wall. For example, the perforations may be located in the top 75%, 60%, 50%, 40%, 30%, 25%, 20%, 15%, 10%, or 5% of the baffle wall. The baffle wall may have greater than or equal to 5, 10, 15, 20, 30, 40, 50, 60, 80, 100, 150, 200, 300, 500, or more perforations. The number of perforations may be dependent upon the size of the baffle wall. For example, a larger baffle wall may have a larger number of perforations. The baffle wall may comprise perforations of uniform size or the size of the perforations may vary across the baffle wall. The perforations may be circular, elliptical, square, triangular, slits, or any other shape. The perforations may have a dimension of greater than or equal to about 0.5 millimeters (mm), 1 mm, 2 mm, 3 mm, 4 mm, 5 mm, 6 mm, 8 mm, 10 mm, 15 mm, 20 mm, 30 mm, 40 mm, 50 mm, or greater. The perforations may have a dimension of less than or equal to about 50 mm, 40 mm, 30 mm, 20 mm, 15 mm, 10 mm, 8 mm, 6 mm, 5 mm, 4 mm, 3 mm, 2 mm, 1 mm, 0.5 mm, or less. The perforations may have a dimension from about 0.5 mm to 1 mm, 0.5 mm to 2 mm, 0.5 mm to 3 mm, 0.5 mm to 4 mm, 0.5 mm to 5 mm, 0.5 mm to 6 mm, 0.5 mm to 8 mm, 0.5 mm to 10 mm, 0.5 mm to 15 mm, 0.5 mm to 20 mm, 0.5 mm to 30 mm, 0.5 mm to 40 mm, 0.5 mm to 50 mm, 1 mm to 2 mm, 1 mm to 3 mm, 1 mm to 4 mm, 1 mm to 5 mm, 1 mm to 6 mm, 1 mm to 8 mm, 1 mm to 10 mm, 1 mm to 15 mm, 1 mm to 20 mm, 1 mm to 30 mm, 1 mm to 40 mm, 1 mm to 50 mm, 2 mm to 3 mm, 2 mm to 4 mm, 2 mm to 5 mm, 2 mm to 6 mm, 2 mm to 8 mm, 2 mm to 10 mm, 2 mm to 15 m, 2 mm to 20 mm, 2 mm to 30 mm, 2 mm to 40 mm, 2 mm to 50 mm, 3 mm to 4 mm, 3 mm to 5 mm, 3 mm to 6 mm, 3 mm to 8 mm, 3 mm to 10 mm, 3 mm to 15 m, 3 mm to 20 mm, 3 mm to 30 mm, 3 mm to 40 mm, 3 mm to 50 mm, 4 mm to 5 mm, 4 mm to 6 mm, 4 mm to 8 mm, 4 mm to 10 mm, 4 mm to 15 m, 4 mm to 20 mm, 4 mm to 30 mm, 4 mm to 40 mm, 4 mm to 50 mm, 5 mm to 6 mm, 5 mm to 8 mm, 5 mm to 10 mm, 5 mm to 15 m, 5 mm to 20 mm, 5 mm to 30 mm, 5 mm to 40 mm, 5 mm to 50 mm, 6 mm to 8 mm, 6 mm to 10 mm, 6 mm to 15 m, 6 mm to 20 mm, 6 mm to 30 mm, 6 mm to 40 mm, 6 mm to 50 mm, 8 mm to 10 mm, 8 mm to 15 m, 8 mm to 20 mm, 8 mm to 30 mm, 8 mm to 40 mm, 8 mm to 50 mm, 10 mm to 15 m, 10 mm to 20 mm, 10 mm to 30 mm, 10 mm to 40 mm, 10 mm to 50 mm, 15 mm to 20 mm, 15 mm to 30 mm, 15 mm to 40 mm, 15 mm to 50 mm, 20 mm to 30 mm, 20 mm to 40 mm, 20 mm to 50 mm, 30 mm to 40 mm, 30 mm to 50 mm, or 40 mm to 50 mm. The perforations in the baffle wall may be open holes. Alternatively, or in addition to, some or all of the perforations may include flow restrainer plugs. A flow restrainer plug may partially or fully block a perforation. The location of the flow restrainer plugs may be used to optimize the flow distribution of the first liquid for select heat source (e.g., server) configurations (e.g., the position or size of the heat generating components).

The baffle may include a flow diverter, as shown in FIG. 4D. The flow diverter may be configured to direct flow or may direct flow of the first liquid around the heat source. The flow diverter may include a channel, tube, pipe, or other structure that routes flow of the first liquid in a select direction or flow pattern. The flow diverter may be a three-dimensional (3D) printed part. The 3D printed part may be adapted to or designed for a specific heat source or electronic component to be cooled. The system may include at least 1, 2, 3, 4, 5, 6, 8, 10 or more flow diverters. The flow diverters may be the same or may be different. For example, the flow diverters may vary in height, width, flow channel size, or any other dimension. A flow diverter may be disposed anywhere within a container or additional container. In an example, one or more flow diverters are disposed between baffle walls. In an additional example, a flow diverter may be coupled to a bottom plate of the baffle.

The system may further include one or more static suction pumps. A static suction pump may be disposed at any location within the container. The container may include at least 1, 2, 3, 4, 6, 8, 10, or more static suction pumps. In an example, the static suction pump is disposed between a baffle wall and a container wall. In another example, the container includes two static suction pumps, each disposed between a different baffle wall and a container wall (e.g., at opposite sides of the container). In another example, the container includes four static suction pumps, each disposed between a baffle wall and a container wall on each side of the container. A static suction pump may comprise a converting structure. The converging structure may be a fixed structure (e.g., not include moving parts) coupled to a baffle wall. Alternatively, or in addition to, the converging structure of may be coupled to a container wall. The converging structure may be coupled to an outer, bottom portion of a baffle wall. The converging structure may include a nozzle-like structure. The converging structure may include one or more fluid flow paths. The one or more fluid flow paths may be circular, elliptical, or elongated fluid flow paths. The converging structure may extend an entire length of the baffle (e.g., in a direction parallel to the length or width of the container). Alternatively, or in addition to, the converging structure may extend across a portion of the baffle. The converging structure may have a point of narrowest or smallest dimension. The narrowest or smallest dimension of the converging structure may be less than or equal to about 50 centimeters (cm), 40 cm, 30 cm, 20 cm, 10 cm, 8 cm, 6 cm, 5 cm, 4 cm, 3 cm, 2 cm, 1 cm, or less. The narrowest or smallest dimension of the converging structure may be greater than or equal to about 1 cm, 2 cm, 3 cm, 4 cm, 5 cm, 6 cm, 8 cm, 10 cm, 20 cm, 30 cm, 40 cm, 50 cm, or more. The narrowest or smallest dimension of the converging structure may be from about 1 cm to 2 cm, 1 cm to 3 cm, 1 cm to 4 cm, 1 cm to 5 cm, 1 cm to 6 cm, 1 cm to 8 cm, 1 cm to 10 cm, 1 cm to 20 cm, 1 cm to 30 cm, 1 cm to 40 cm, 1 cm to 50 cm, 2 cm to 3 cm, 2 cm to 4 cm, 2 cm to 5 cm, 2 cm to 6 cm, 2 cm to 8 cm, 2 cm to 10 cm, 2 cm to 20 cm, 2 cm to 30 cm, 2 cm to 40 cm, 2 cm to 50 cm, 3 cm to 4 cm, 3 cm to 5 cm, 3 cm to 6 cm, 3 cm to 8 cm, 3 cm to 10 cm, 3 cm to 20 cm, 3 cm to 30 cm, 3 cm to 40 cm, 3 cm to 50 cm, 4 cm to 5 cm, 4 cm to 6 cm, 4 cm to 8 cm, 4 cm to 10 cm, 4 cm to 20 cm, 4 cm to 30 cm, 4 cm to 40 cm, 4 cm to 50 cm, 5 cm to 6 cm, 5 cm to 8 cm, 5 cm to 10 cm, 5 cm to 20 cm, 5 cm to 30 cm, 5 cm to 40 cm, 5 cm to 50 cm, 6 cm to 8 cm, 6 cm to 10 cm, 6 cm to 20 cm, 6 cm to 30 cm, 6 cm to 40 cm, 6 cm to 50 cm, 8 cm to 10 cm, 8 cm to 20 cm, 8 cm to 30 cm, 8 cm to 40 cm, 8 cm to 50 cm, 10 cm to 20 cm, 10 cm to 30 cm, 10 cm to 40 cm, 10 cm to 50 cm, 20 cm to 30 cm, 20 cm to 40 cm, 20 cm to 50 cm, 30 cm to 40 cm, 30 cm to 50 cm, or 40 cm to 50 cm. Flow of the first liquid through the converging structure may generate a suction force that pulls liquid from the top of the container and generates forced fluid flow.

The system may further include one or more recirculation loops. The system may include at least 1, 2, 3, 4, 6, 8, 10, or more recirculation loops. In an example, the system includes one recirculation loop. In another example, the system includes two recirculation loops. A recirculation loop may be configured to provide or may provide forced convection of the first liquid. A recirculation loop may include piping, a variable speed recirculation pump or both piping and a recirculation pump. The recirculation loop(s) may be disposed inside the container, outside the container, or both inside and outside the container. In an example, a portion (e.g., piping) of the recirculation loop(s) may be disposed inside the container and another portion (e.g., piping or pumps) of the recirculation loop(s) may be disposed external to the container.

The container may further include one or more relief valves or pressure regulators. A relief valve or pressure regulator may be configured to maintain or may maintain a pressure in the container below a threshold value or within a given pressure range. A relief valve or pressure regulator may be disposed in the lid, in a wall of the container, on the bottom of the container, or any combination thereof. In an example, the system includes one or more relief valves. In another example, the system includes one or more pressure regulators. In another example, the system includes both a relief valve and pressure regulator. A relief valve may be coupled to or fluidically connected to a secondary expansion tank. Alternatively, a relief valve is open to an atmosphere external to the tank. The relief valve or pressure relief valve may be configured to prevent or may prevent over pressure of the container. The relief valve may maintain a pressure within the container (e.g., maintain a headspace pressure or fluid pressure) below a threshold value. The threshold value may be less than or equal to 5 bar, 4 bar, 3 bar, 2 bar, 1 bar, 0.9 bar, 0.8 bar, 0.7 bar, 0.6 bar, 0.5 bar, or less. The pressure regulator may maintain the pressure within a given pressure range. The pressure regulator may maintain a pressure from about 0.5 bar to about 0.6 bar, 0.5 bar to about 0.7 bar, 0.5 bar to about 0.8 bar, 0.5 bar to about 0.9 bar, 0.5 bar to about 1 bar, 0.5 bar to about 2 bar, 0.5 bar to about 3 bar, 0.5 bar to about 4 bar, 0.5 bar to about 5 bar, 0.6 bar to about 0.7 bar, 0.6 bar to about 0.8 bar, 0.6 bar to about 0.9 bar, 0.6 bar to about 1 bar, 0.6 bar to about 2 bar, 0.6 bar to about 3 bar, 0.6 bar to about 4 bar, 0.6 bar to about 5 bar, 0.7 bar to about 0.8 bar, 0.7 bar to about 0.9 bar, 0.7 bar to about 1 bar, 0.7 bar to about 2 bar, 0.7 bar to about 3 bar, 0.7 bar to about 4 bar, 0.7 bar to about 5 bar, 0.8 bar to about 0.9 bar, 0.8 bar to about 1 bar, 0.8 bar to about 2 bar, 0.8 bar to about 3 bar, 0.8 bar to about 4 bar, 0.8 bar to about 5 bar, 0.9 bar to about 1 bar, 0.9 bar to about 2 bar, 0.9 bar to about 3 bar, 0.9 bar to about 4 bar, 0.9 bar to about 5 bar, 1 bar to about 2 bar, 1 bar to about 3 bar, 1 bar to about 4 bar, 1 bar to about 5 bar, 2 bar to about 3 bar, 2 bar to about 4 bar, 2 bar to about 5 bar, 3 bar to about 4 bar, 3 bar to about 5 bar, of 4 bar to 5 bar. In an example, the pressure regulator maintains the pressure from about 0.9 bar to 1.1 bar.

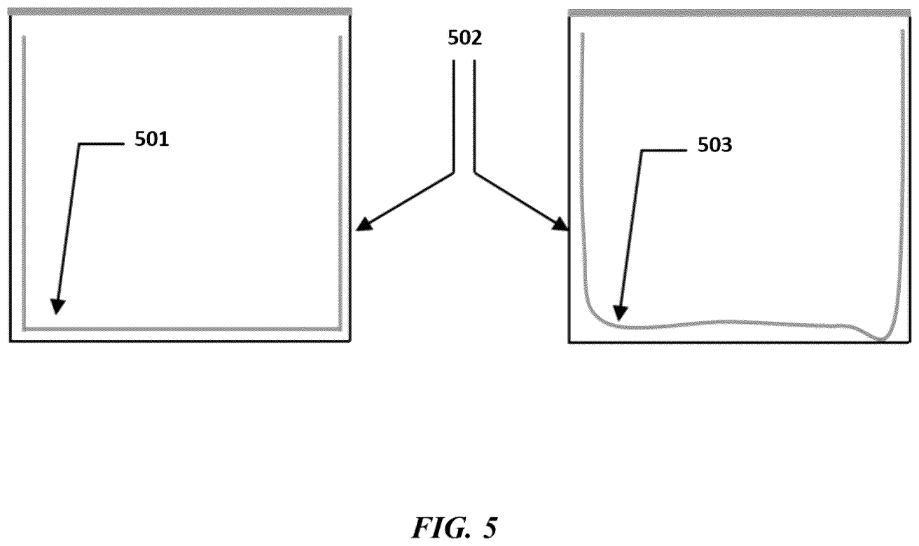

The container may further include a liner, as shown in FIG. 5. The liner may be a rigid liner 501 or a deformable liner 503. In an example, the liner is a rigid liner 501. In another example, the liner is a deformable liner 503. The liner may be removable or may be integrated with the container 502. In some embodiments, the removal or integration of the liner may be controlled by commands from a remote platform. In an example, the liner is removable. In another example, the liner is integrated with the container. The liner may be made of any material compatible with the first liquid. The liner may be a first liquid compatible rubber or plastic material. The liner may be configured to seal or may seal the container. The liner may be further configured to avoid liquid spills. Using a liner may provide several advantages, for example, the liner may permit the use of a non-sealed container (e.g., metallic container without liquid proof welds or connections).

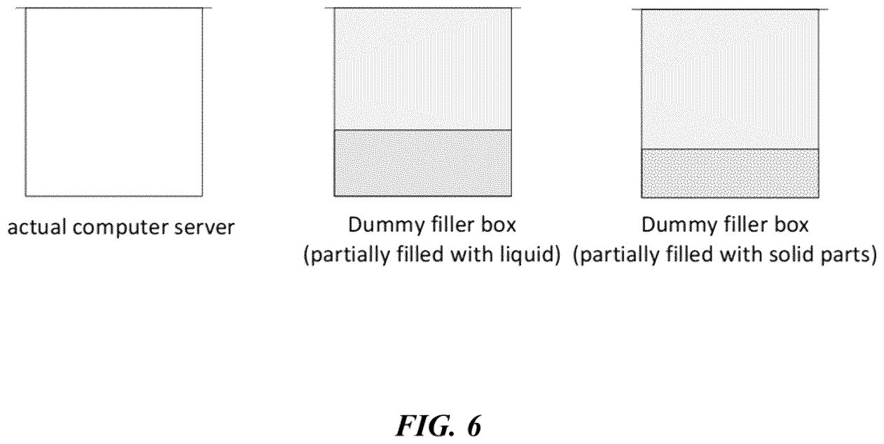

The system may further include a displacement volume, as shown in FIG. 6. The container may be configured to hold or may hold multiple electronic components (e.g., servers). Each electronic component may displace a volume of the first liquid. In an example, the container may include one or more empty slots and those empty slots may comprise additional first liquid volume. Alternatively, an empty slot may be filled with a displacement volume. The displacement volume may be shaped substantially the same as a heat source (e.g., computer server) such that a heat source may be exchanged for a displacement volume. The displacement volume may be formed of metals or rigid plastics that are compatible with the first liquid. The displacement volumes may comprise an internal material such as a liquid or solid parts. The internal material may increase the weight of the displacement volume and counteract any buoyancy forces. The displacement volume may be configured to reduce a volume of the first liquid or may reduce a volume of the first liquid as compared to a system without the displacement volume. A displacement volume may further be configured to avoid or reduce diversion of flow of the first liquid to the empty region. Diversion of flow to an empty region (e.g., region without a heat source) may reduce cooling efficiency. Reducing the volume of the first liquid may decrease the cost of the system, increase cooling efficiency, or both.

The container may further comprise one or more cable outlets, as shown in FIG. 7. The cable outlet may be configured to permit or may permit a cable 703 connected to the heat source to exit the container while maintaining the seal of the container. In some embodiments, the permission of the cable 703 to be connected to the heat source may be controlled/given by commands from a remote platform. Cables may include electrical connections, ethernet connections, or any other cable. The cable outlet may be configured to permit multiple cables to span an interior and exterior portion of the container. The cable outlet may be disposed in a headspace 702 of the container such that the first liquid 701 does not contact the cable outlet and spill or flow out of the container. The cable outlet may be configured to permit a portion of a cable or multiple cables 703 to be disposed internal to the container and another portion of the cable or cables 703 to be disposed external to the container. In some embodiments, the selection of portion of the cable or cable 703 to be disposed external to the container may be controlled by commands from a remote platform. The cable outlet may be configured to seal or may seal the container. The cable outlet may comprise a conduit. The cable may be disposed in the conduit. The conduit may further include a third liquid 704 configured to seal or that seals the cable outlet. The conduit may comprise a shape configured to prevent fluid from spilling out of the container or conduit. For example, the conduit may comprise a p-trap or u-shape to prevent fluid disposed at the bottom of the p-trap or u-shape from flowing out of the conduit.

The system further comprises one or more processors. The one or more processors may be coupled to the heat exchanger. The one or more processors may be configured to regulate or may regulate flow of the second liquid through the heat exchanger. The one or more processors may be coupled to the recirculation loop. The one or more processors may be configured to regulate a flow or may regulate a flow of the first liquid through the recirculation loop.

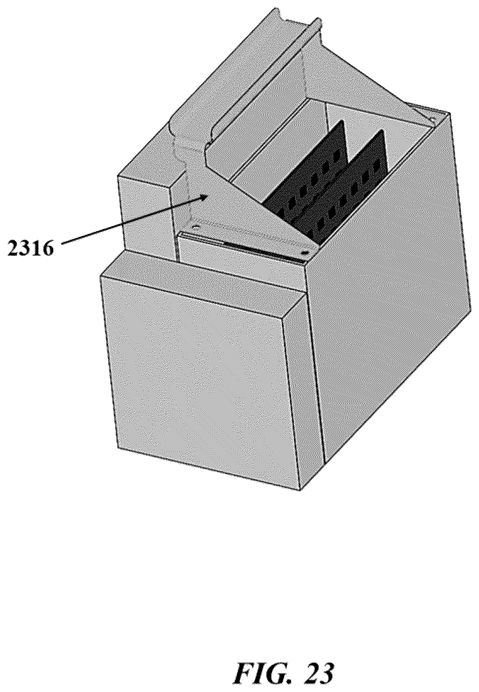

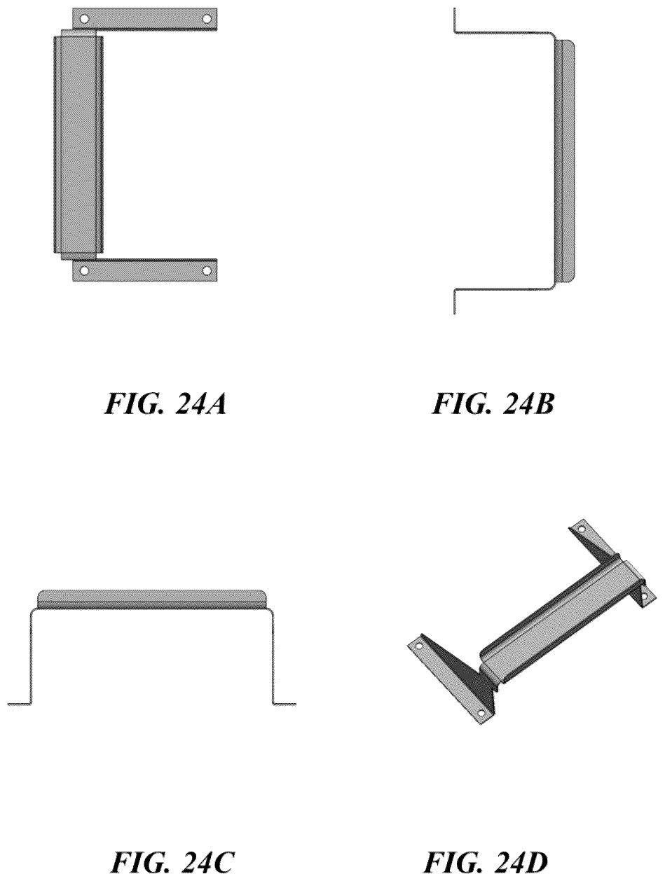

The cooling system may be usable for cooling one or more miners (e.g., mining machine, bitcoin miner, or other electronic components comprising or utilizing applicant-specific integrated circuitry (ASICs)). The one or more miners (e.g., mining machines) may be usable for crypto currency mining, proof of work network such as Web3 (e.g., decentralized version of the internet), or any other mining operations. Miners or mining machines may generate thermal energy that may be dissipated via cooling fans, which utilize significant energy. Alternatively, mining machines may be cooled using the immersion cooling systems and methods described herein. Using immersion cooling for mining machines may decrease energy consumption as compared to mining machines cooled using cooling fans. A mining machine may or may not include a cooling fan. Prior to cooling a mining machine using an immersion cooling system, the fan(s) may be removed. In an example, a mining machine may be positioned in the immersion cooling system described herein in a vertical configuration, for example, with the cooling fan location facing upward (e.g., towards a lid of the cooling system). Alternatively, or in addition to, the mining machines may be placed horizontal such that the fan location is disposed facing one or more sidewalls of the cooling system tank. In a vertical configuration, placing the mining machine in the cooling system and removing the mining machine from the cooling system may be challenging. A wireless handle, as shown in FIG. 23, may be installed in place of one or more fans of a mining machine. The wireless handle 2316 may be configured as a direct replacement for the cooling fan(s) (e.g., using the same screws, screw holes, location, or any combination thereof as the cooling fan(s). Alternatively, or in addition to, the wireless handle may be mounted in a location other than the location of the cooling fan(s). The wireless handle 2316 may be configured to balance the weight of the mining machine and mining machine power supply such that the mining machine may be lifted straight out of the cooling system. FIGS. 24A-24D show various views of the wireless handle 2316 of FIG. 23. FIG. 24A shows a side view of an example wireless handle. FIG. 24B shows a front view of an example wireless handle. FIG. 24C shows a lateral view of an example wireless handle. FIG. 24D shows a perspective view of an example wireless handle.

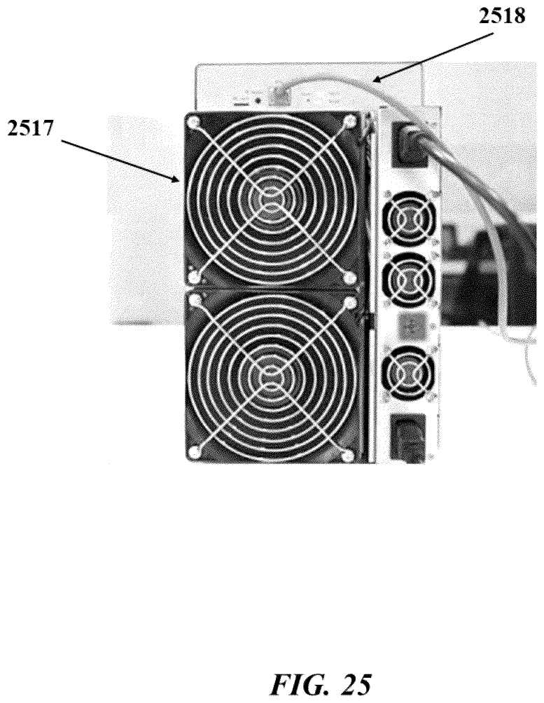

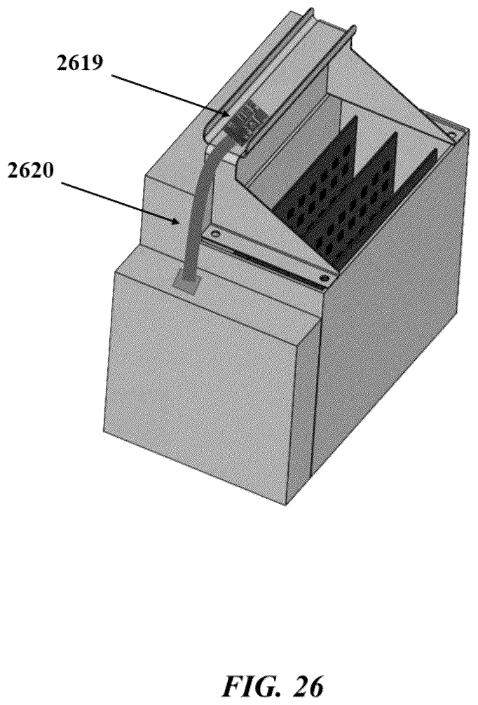

Mining machines may be connected to a network through a cable (e.g., network cable such as an ethernet cable). FIG. 25 shows an example mining machine comprising fans 2517 attached to a network via an ethernet cable 2518. It may be challenging to pass cables (e.g., ethernet cables, power cables, etc.) from the tank of the cooling system to an external environment. For example, in a two-phase immersion cooling system, hermetically sealing the cooling system may be challenging and, if not hermetically sealed, cooling liquid may be lost due to evaporation. To avoid passing cables from the mining machine to an external environment, the wireless handle may include a wireless emitter connected to the controller of the miner, as shown in FIG. 26. The wireless emitter 2619 may be disposed at any location on the wireless handle. The wireless emitter 2619 may be connected to the controller of the miner via a cable (e.g., ethernet cable) 2620. Using a wireless emitter 2619 may reduce a number of cables or eliminate cables passing from the tank of the cooling system to an external environment to permit sealing of the cooling system.

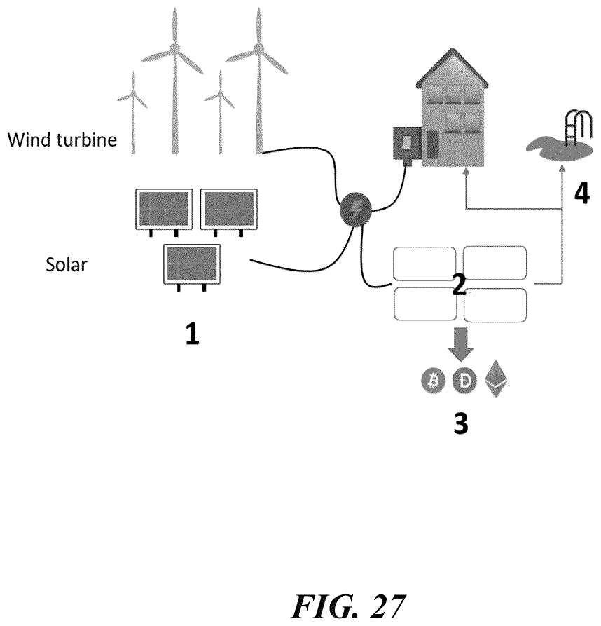

The cooling systems described herein may be used with or integrated with a renewable energy system. Using renewable energy sources may be challenging due to cost and difficulty of energy storage. Electric energy batteries may be used for energy storage but may be limited in terms of storage capacity and efficiency. Additionally, selling extra electricity back to the grid may not be efficient or possible in all energy generation locations. Alternatively, or in addition to, a cooling system may be used as an energy storage system. For example, immersion cooled miners may be used as an energy storage system. Using air cooled mining machines as an energy storage system may not be possible or may be challenging due to the energy used to run the fans, excess or nuisance noise, and/or cool the mining machines. Alternatively, immersion-cooled mining machines may have the benefit of using less energy and being quieter than air cooled counterparts. FIG. 27 shows an example system integrating renewable energy generation with an immersion cooling system for energy storage. Energy from a renewable resource farm or home renewable energy source (1) (e.g., from a wind farm, solar farm, home solar system, etc.) may be used to power the mining machines (2) (e.g., for cryptocurrency mining, blockchain processing, or any other kind of proof of work network (e.g., Web3)). Powering the mining machines with unused electricity may generate additional revenue from the extra energy (3). The extra energy (3) may additionally be converted to thermal energy by powering the mining machines (2). The fluid used to cool the mining machines (2) may be heated by the mining machines. The cooling system may include an inlet and an outlet to circulate cooling fluid within the cooling system. The cooling fluid leaving the cooling system may be heated. The heated cooling fluid may be used for secondary heating (4) (e.g., heating or warming a building, warming water for personal use, warming a pool, or any other warming use). Secondary heating, as used herein, may include using heat generated from the cooling system to supplement another heating system or as a standalone heating system. Integrating renewable energy sources with immersion cooled mining machines may increase the sustainability and accessibility of blockchain based technologies. In turn, increasing sustainability and accessibility of blockchain based technologies may permit or increase network decentralization.

The system described elsewhere herein may be provided as a kit. The kit may include a container configured to cool a heat source. The container may be configured to hold or otherwise be in contact with the heat source. The kit may further include the first liquid, second liquid, liquid lid, float, or any combination thereof. The liquid components may be portioned to a specific volume used by the system. Alternatively, or in addition to, the liquid components may be provided in excess of a volume used by the system. The liquid components may be portioned and provided individually such that each liquid component is provided separately. Alternatively, or in addition to, the liquid components of the system may be portioned and provided in a single container (e.g., the liquid components may be pre-mixed). Alternatively, or in addition to, select liquid components (e.g., the first liquid and liquid lid) may be provided together in a single container and other liquid components (e.g., second liquid) may be provided in a separate container. The liquid components provided together may be a milky mixed fluid configured to phase separate once added to the system. Alternatively, the liquid components provided together may be a multilayer, phase separated composition.

### Methods for Cooling a Heat Source

In another aspect, the present disclosure provides a method for cooling a heat source. The method may include providing a cooling system comprising a container, a baffle, a heat exchanger, or any combination thereof. The container may include container walls, a first liquid, and a heat source submerged in the first liquid. The baffle may be disposed between the heat source and the container wall. The heat exchanger may be in thermal communication with and fully submerged in the first liquid. The first liquid may be in thermal communication with the heat source. The method may further include transferring thermal energy from the heat source to the first liquid. During transfer of thermal energy, the baffles may be used to direct flow the first liquid away from the heat source. The method may further include using the heat exchanger to flow a second liquid. The second liquid may remove thermal energy from the first liquid to cool the heat source.

In another aspect, the present disclosure provides a method for cooling a heat source. The method may include providing a cooling system comprising a container, a baffle, a recirculation loop, or any combination thereof. The container may include a container wall, a first liquid, and a heat source submerged in the first liquid. The first liquid may be in thermal communication with the heat source. The baffle may be disposed between the heat source and the container wall. The recirculation loop may include a passageway and a pump. The passageway may include a converging structure disposed between the baffle and the container wall. The pump may direct the flow of the first liquid through the converging structure. The method may further include transferring thermal energy from the heat source to the first liquid. During transferring the baffles may be used to direct flow of the first liquid away from the heat source. The method may further include using the pump to direct the first liquid through the converging structure of the passageway to generate flow of the first liquid between the baffle and the container wall to cool the heat source.

The methods of the present disclosure may be used in conjunction with any of the systems described elsewhere herein.

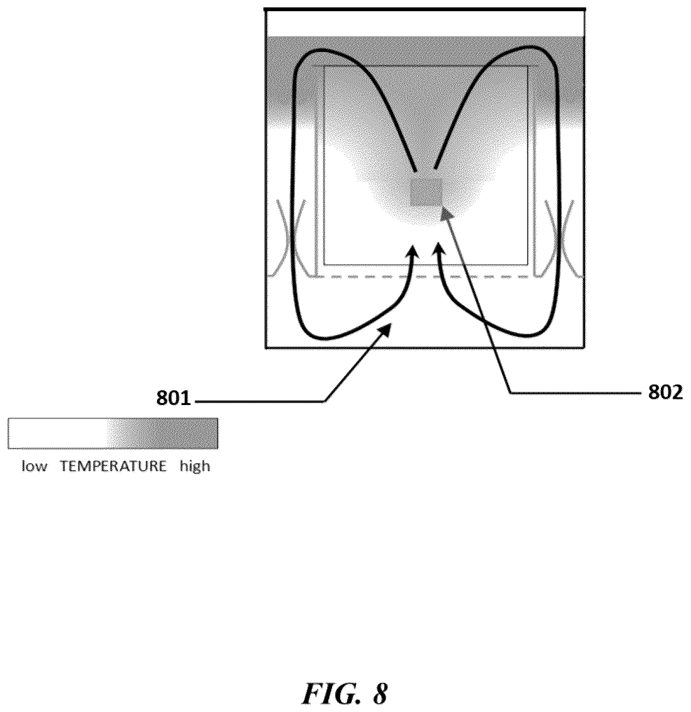

The method may include immersing a heat source in the first liquid. The heat source may be fully submerged or immersed in the first liquid. Alternatively, the heat source may be partially submerged in the first liquid. The system may be operated in a single-phase mode, as shown in FIG. 8. During single-phase operation the first liquid may not undergo a phase change from a liquid to a gas. During operation, the heat source (e.g., heat generating components such as computer processing units) 802 may generate and release thermal energy. The thermal energy may be dissipated by the cooling system via transfer of thermal energy from the heat source 802 to the first liquid 801. Transfer of thermal energy from the heat source 802 to the first liquid 801 may increase the local temperature of the first liquid 801, lower the density of the first liquid 801, and cause the warmer portion of the first liquid 801 to rise to the top of the container due to buoyancy forces. The warm first liquid may contact the heat exchanger and transfer thermal energy from the first liquid to the heat exchanger. Transfer of thermal energy to the heat exchanger may decrease a temperature of the first liquid proximate to the heat exchanger, increase the density of the first liquid, and cause the cooled first liquid to flow downward and towards to the bottom of the container. The cycle of heating and cooling of the first liquid may generate a circulation loop generated by natural convection of the first liquid.

During heating and cooling of the first liquid, the baffle may direct the rising fluid to the heat exchanger. The heat exchanger may include a plurality of tubes and the method may include flowing the second fluid through the plurality of tubes. The heat exchanger may be coupled to a pump. The method may further use the pump to direct flow of the second liquid through the heat exchanger. In an example, the heat exchanger may be disposed between the baffle and the container wall. Alternatively, or in addition to, the heat exchanger may be disposed in any position near the top of the container. Alternatively, or in addition to, the method may further include flowing the first liquid to an additional container comprising the heat exchanger. The additional container may be in fluid communication with the container via tubing or piping. The system may include one or more additional pumps that direct flow of heated first liquid from an upper region of the container to the additional container and flow of cooled first liquid from the additional container back to the container. The position, size, and shape of the heat exchanger may be determined and dependent upon the shape and heat generation capabilities of the heat source (e.g., servers). The heat exchanger may be fully submerged in the first liquid. Fully submerging the heat exchanger within the first liquid may improve the efficiency of transfer of thermal energy from the first liquid to the second liquid.

The method may further include the use of a baffle to direct the first liquid around the container. The baffle may direct the first liquid to and across the heat source. The baffle may further direct the rising heated first liquid towards the heat exchanger. Additionally, the baffle may direct the first liquid that has been cooled by the heat exchanger along a wall of the container, through the converging structure of the static suction pump, and toward the bottom of the container. The baffle may include a bottom plate. The bottom plate may comprise perforations. The perforation may permit flow of the first liquid though the bottom plate and toward the heat source. The baffle may further include walls. The walls may include perforations that permit flow of the first liquid through the baffle walls in a lateral motion. The baffle may further include a flow diverter. The flow diverter may be used to direct flow of the first liquid around the heat source. Additionally, the baffle may be used to support the heat source. The heat source may include a lip or overhang that hook or sets on an upper edge of the baffle, thus permitting the heat source to hang from the baffle.

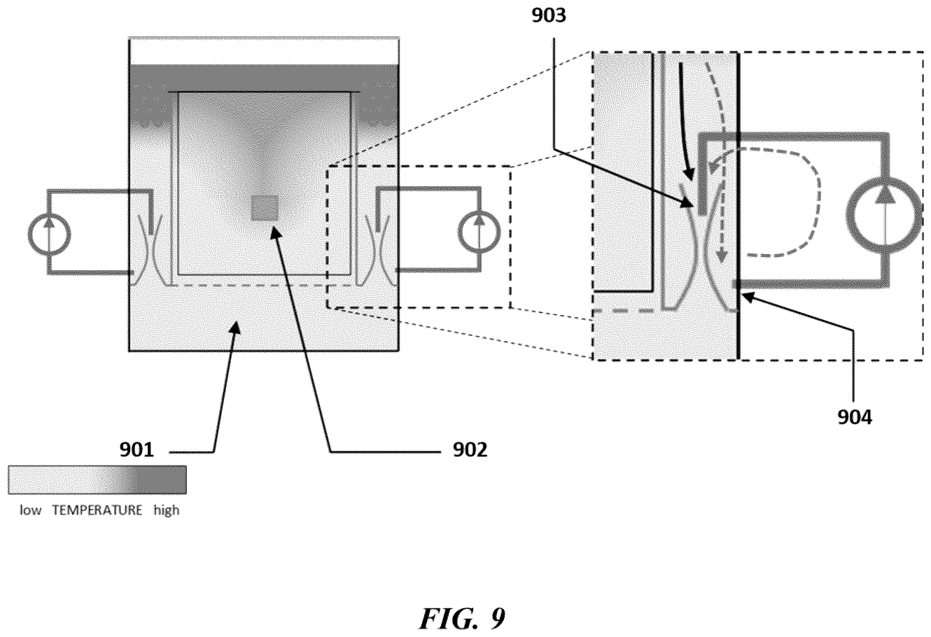

Flow of the first liquid may be boosted or improved using one or more recirculation loops, as shown in FIG. 9. A recirculation loop may include a variable speed pump to provide an adjustable flow rate. The variable speed pump may permit tuning of the flow rate of the first liquid across the heat source and towards the heat exchanger. Tuning the flow rate of the first liquid may permit control or modulation of the temperature of the heat source. The recirculation loop may include a recirculation loop inlet 904. The recirculation loop inlet 904 may pull the first liquid 901 from an outer side of the converging structure of the static suction pump. The recirculation loop may further include a recirculation loop outlet 903 that directs the first liquid 901 into the converging structure of the static suction pump. In some embodiments, the recirculation loop outlet 903 may direct the first liquid 901 based on commands from a remote platform. Pushing the fluid into the converging structure of the static suction pump may generate a suction effect that pulls the first liquid from the top of the container toward the bottom of the container and to the heat source 902. The magnitude of the suction force may be increased by increasing the flow rate of the first liquid to the converging structure. As heat is generated by the heat source, a temperature of the heat source may increase. To prevent the temperature from raising, or to reduce the magnitude of the temperature rise, the flow rate of the first liquid may be increased by increasing the flow rate of the recirculation pump. Increasing flow rate of first liquid may improve or increase the rate of heat transfer between the heat source and the first liquid. Furthermore, increasing the flow rate of the first liquid may increase the rate of heat transfer from the first liquid to the heat exchanger or heat exchanger tubes. The method may further include using a blower to cool or control a temperature of the first liquid or at least a portion of the first liquid. The dynamic between the amount of thermal energy generated by the heat source and flow rate of the first liquid may generate a stabilizing feedback mechanism to permit control and stabilization of the heat source within a given temperature range. Maintaining the temperature of the heat source within a given temperature range may maximize the efficiency and reliability of the heat generating components.

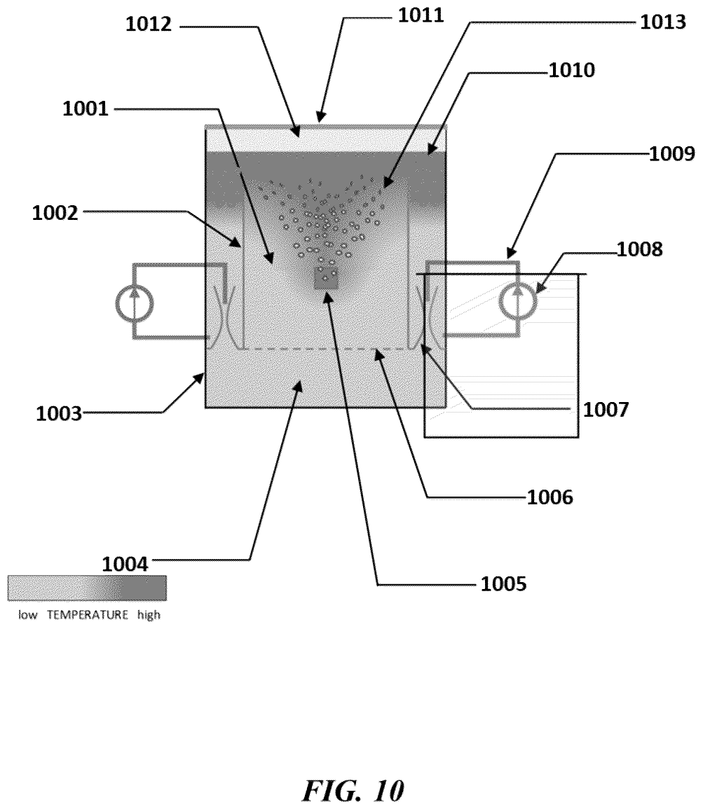

Alternatively, the system may be operated in a two-phase mode. Similar control mechanisms may be used for both the single-phase mode and the two-phase mode of operation. For example, and as shown in FIG. 10, the heat source 1001 may include a heat generating component 1005 submerged or immersed in the first liquid 1004 within a container 1003. Upon contacting the heat source 1001, the first liquid 1004 may undergo a phase transition from a liquid to a vapor. The phase transition may generate vapor bubbles 1013 on a surface of the heat source. The generation of vapor bubbles 1013 may permit efficient heat dissipation of heat generated by the heat source 1001. The generated vapor bubbles 1013 may be directed from the heat source 1001 to the heat exchanger 1010 by the baffle 1002. The system may further include a recirculation loop 1009 comprising a variable speed recirculation pump 1008. In some embodiments, the speed of the variable speed recirculation pump 1008 may be controlled by commands from a remote platform. The recirculation loop 1009 may direct the first liquid cooled and condensed by the heat exchanger 1010 to the converting structure of the static suction pump 1007. The system may further include a lid 1011 to seal the container 1003. The lid 1011 may be in contact with the first liquid 1004. Alternatively, the container 1003 may include air or an inert gas 1012 and the air or inert gas 1012 may contact the lid 1011.

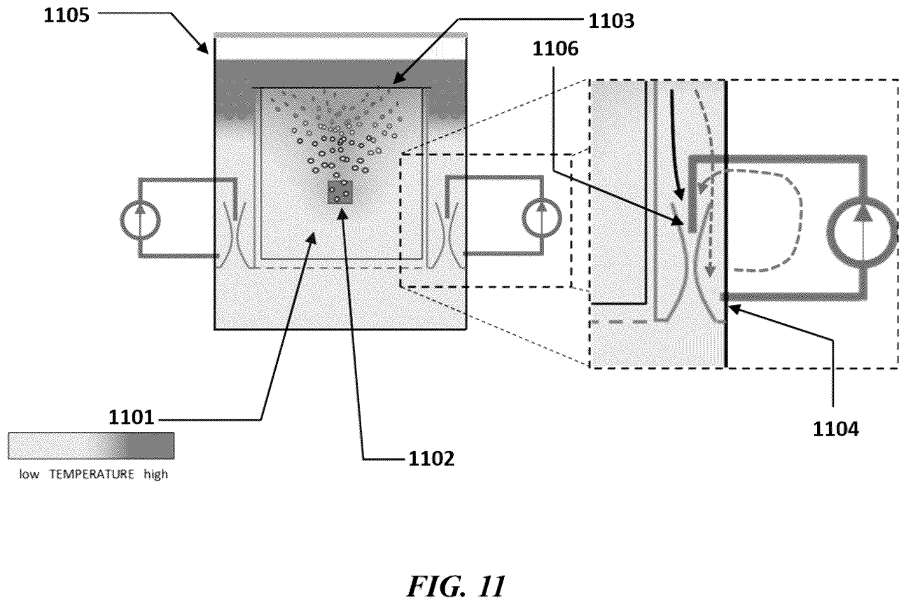

The two-phase cooling mode may use subcooled nucleate boiling or saturated boiling. In a saturated boiling mode, the first liquid may contact the heat source and undergo a phase transition to a vapor phase. The generated vapor bubbles may rise in the container and merge with an upper vapor plenum where the vapor contacts cold walls (e.g., of a condenser unit) an re-condenses. In a system using saturate boiling conditions, the temperature of the liquid may be the liquid boiling temperature. Alternatively, the two-phase cooling mode may use subcooled nucleate boiling to cool the heat source. A subcooled fluid may be a fluid with a temperature below a boiling temperature of the first liquid. The surface of the heat source may exceed the boiling temperature of the first liquid such that, upon contact of the first liquid with the heat source, vapor bubbles may be generated on a surface of the heat source. The vapor bubbles may re-condense within the first liquid rather than in a headspace above the first liquid. In turn, as the vapor bubbles are generated and re-condense, the temperature of the first liquid increases. Two-phase cooling using subcooled nucleate boiling may further be assisted by a recirculation loop, as shown in FIG. 11. The vapor bubbles 1103 may be directed from the heat source 1102 towards the heat exchanger by the baffle. The heat exchanger may cool the first liquid 1101 in an area proximate to the heat exchanger. The cooled first liquid may permit the vapor bubbles to re-condense in the first liquid rather than in the headspace 1105. The cooled first liquid may contact the heat exchanger or flow proximate to the heat exchanger and downwards toward the converging structure of the static suction pump. The recirculation loop may include a recirculation loop inlet 1104 that may pull the first liquid 1101 from an outer side of the converging structure of the static suction pump. The recirculation loop may further include a recirculation loop outlet 1106 that directs the first liquid 1101 into the converging structure of the static suction pump. In some embodiments, the recirculation loop outlet 1106 may direct the first liquid 1101 based on commands from a remote platform. Pushing the fluid into the converging structure of the static suction pump may generate a suction effect that pulls the first liquid from the top of the container toward the bottom of the container and to the heat source 1102. The method may further include using a blower to cool or control a temperature of the first liquid or at least a portion of the first liquid.

The use of subcooled nucleate boiling and described flow control method may have various advantages over saturated two-phase immersion cooling systems. For example, the use of subcooled nucleate boiling may permit the system to reach higher heat flux limits, thus increasing the cooling efficiency of the system. Increasing the cooling efficiency of the system may permit the use of more powerful heat generating components (e.g., central processing units). The increase in efficiency may be further enhanced by modifying a surface of the heat source, for example, by etching or coating the heat generating components with micro- or nano-structures to increase bubble nucleation. The structures may include micro-pillars or any other 3D micro-feature. The 3D structures may be generated by ion etching, laser-etching, sandblasting, or any other treatment to generate structures on the surface of the electronic component. Alternatively, or in addition to, the electronic component may include a coating that enhances nucleation of bubbles on a surface of the electronic component. The 3D structure or coating may increase the area density of bubble nucleation and surface wettability with the first liquid. Increasing bubble nucleation may, in turn, increase heat dissipation efficiency of the subcooled first liquid. Additionally, the use of subcooled nucleate boiling may permit regulation of the temperature of the heat source. For example, the flow rate of the first liquid may be adjusted to control a temperature of the first liquid. Controlling the temperature of the first liquid may, in turn, control the temperature of the heat source. Controlling the temperature of the heat source may provide various benefits, such as, for example, increasing the performance and longevity of the heat source by maintaining the temperature of the heat source within a given range. Additionally, the tunability of the flow rate of the first liquid may permit the temperature of the heat source to be tuned. The use of subcooled nucleate boiling may further decrease or reduce loss of the first liquid during start up and operation of the system as compared to a system using saturated boiling.

The first liquid may be a coolant. The first liquid may directly contact the heat source. In an example, the first liquid is a dielectric liquid. The dielectric liquid may have high dielectric strength (e.g., be an effective dielectric), high thermal stability, be inert against components of the system, non-flammable, low toxicity, and have good heat transfer properties. In another example, the first liquid is a dielectric liquid that directly contacts the heat source. The second liquid may be a coolant. In an example, the second liquid is water. The first liquid and the second liquid may be the same liquid or may be different liquids. In an example, the first liquid and the second liquid are the same liquid. In another example, the first liquid and the second liquid are different liquids. In an example, the first liquid is a dielectric liquid and the second liquid is water. The first liquid, the second liquid, or both may comprise a dielectric liquid. The dielectric liquid may be mineral oil, hexane, heptane, castor oil, silicone oil, polychlorinated biphenyls, benzene, engineered fluids such as methoxy-nonafluorobutane or ethoxy-nonafluorobutane, or any combination thereof. The first liquid or the second liquid may comprise a coolant. The coolant may be water, deionized water, glycol, ethylene glycol, nanofluids (e.g., suspension of nanoparticles in a fluid), refrigerant, or any combination thereof. The first liquid or the second liquid may be part of a refrigeration cycle. The refrigeration cycle may include a compressor, condenser, evaporator, expansion chamber, flow metering device, or any combination thereof. The refrigeration cycle may be configured to permit or may permit the first liquid or the second liquid to reach a lower temperature and enhance cooling. For example, the second liquid and heat exchanger may be part of a refrigeration cycle to permit the second liquid to reach a temperature that is lower than an ambient temperature (e.g., lower than approximately 20° C.).

The flow rate of the first liquid may be controlled or regulated such that the temperature of the first liquid is less than or equal to 100° C., 90° C., 80° C., 70° C., 60° C., 50° C., 40° C., 30° C., 25° C., 20° C., 15° C., 10° C., 8° C., 6° C., 4° ° C., 2° C., 0° C., −2° C., −4° C., −6° C., −8° C., −10° C., −15° C., −20° C., or less. The flow rate of the first liquid may be controlled or regulated to maintain the temperature of the first liquid from about −20° C. to −15° C., −20° C. to −10° C., −20° C. to −5° C., −20° ° C. to 0° ° C., −20° C. to 5° ° C., −20° C. to 10° C., −20° C. to 20° C., −20° C. to 30° C., −20° C. to 40° C., −20° ° C. to 50° C., −20° C. to 60° C., −20° C. to 70° C., −20° C. to 80° C., −20° C. to 90° C., −20° C. to 100° C., −15° C. to −10° C., −15° C. to −5° C., −15° C. to 0° C., −15° C. to 5° C., −15° C. to 10° ° C., −15° C. to 20° C., −15° ° C. to 30° C., −15° C. to 40° C., −15° C. to 50° C., −15° C. to 60° C., −15° C. to 70° C., −15° C. to 80° C., −15° C. to 90° ° C., −15° C. to 100° C., −10° C. to −5° C., −10° C. to 0° ° C., −10° C. to 5° C., −10° C. to 10° C., −10° C. to 20° ° C., −10° C. to 30° ° C., −10° C. to 40° C., −10° C. to 50° C., −10° C. to 60° C., −10° C. to 70° C., −10° C. to 80° C., −10° C. to 90° C., −10° C. to 100° C., −5° C. to 0° C., −5° C. to 5° C., −5° C. to 10° C., −5° C. to 20° C., −5° C. to 30° C., −5° C. to 40° C., −5° ° C. to 50° C., −5° C. to 60° C., −5° C. to 70° C., −5° C. to 80° C., −5° C. to 90° C., −5° C. to 100° C., 0° C. to 5° C., 0° C. to 10° C., 0° C. to 20° C., 0° C. to 30° ° C., 0° C. to 40° C., 0° C. to 50° C., 0° C. to 60° C., 0° C. to 70° C., 0° C. to 80° C., 0° C. to 90° C., 0° C. to 100° C., 5° ° C. to 10° C., 5° C. to 20° C., 5° C. to 30° C., 5° C. to 40° C., 5° C. to 50° C., 5° C. to 60° C., 5° ° C. to 70° C., 5° C. to 80° C., 5° C. to 90° C., 5° C. to 100° ° C., 10° C. to 20° C., 10° C. to 30° C., 10° C. to 40° C., 10° C. to 50° C., 10° ° C. to 60° C., 10° C. to 70° C., 10° C. to 80° C., 10° C. to 90° C., 10° ° C. to 100° C., 20° ° C. to 30° C., 20° C. to 40° C., 20° C. to 50° C., 20° C. to 60° C., 20° C. to 70° C., 20° C. to 80° C., 20° C. to 90° C., 20° C. to 100° C., 30° C. to 40° C., 30° C. to 50° C., 30° C. to 60° C., 30° C. to 70° C., 30° C. to 80° C., 30° C. to 90° ° C., 30° C. to 100° C., 40° C. to 50° C., 40° C. to 60° C., 40° ° C. to 70° ° C., 40° ° C. to 80° C., 40° C. to 90° C., 40° C. to 100° C., 50° C. to 60° C., 50° C. to 70° C., 50° C. to 80° C., 50° C. to 90° C., 50° C. to 100° C., 60° C. to 70° C., 60° C. to 80° C., 60° C. to 90° C., 60° ° C. to 100° C., 70° C. to 80° C., 70° C. to 90° C., 70° C. to 100° C., 80° C. to 90° C., 80° C. to 100° C., or 90° ° C. to 100° C. The flow rate of the first liquid may be controlled or regulated such that the temperature of the heat source is less than or equal to about 100° C., 90° C., 80° C., 70° C., 60° C., 50° C., 40° C., 30° C., 25° C., 20° C., 15° C., 10° C., 8° C., 6° C., 4° C., 2° C., 0° C., −2° C., −4° C., −6° ° C., −8° C., −10° C., −15° C., −20° C., or less. The flow rate of the first liquid may be controlled or regulate to maintain the temperature of the heat source from about 0° C. to 5° C., 0° C. to 10° C., 0° C. to 20° C., 0° C. to 30° C., 0° C. to 40° C., 0° C. to 50° C., 0° C. to 60° C., 0° C. to 70° C., 0° C. to 80° C., 0° C. to 90° C., 0° C. to 100° C., 5° C. to 10° C., 5° C. to 20° C., 5° C. to 30° C., 5° C. to 40° C., 5° C. to 50° C., 5° C. to 60° C., 5° ° C. to 70° C., 5° C. to 80° C., 5° C. to 90° C., 5° C. to 100° C., 10° C. to 20° C., 10° ° C. to 30° C., 10° C. to 40° C., 10° C. to 50° C., 10° C. to 60° C., 10° C. to 70° C., 10° C. to 80° C., 10° ° C. to 90° C., 10° C. to 100° C., 20° C. to 30° C., 20° C. to 40° C., 20° C. to 50° C., 20° C. to 60° C., 20° ° C. to 70° C., 20° C. to 80° C., 20° C. to 90° ° C., 20° C. to 100° C., 30° C. to 40° C., 30° C. to 50° C., 30° ° C. to 60° C., 30° C. to 70° C., 30° C. to 80° C., 30° C. to 90° C., 30° C. to 100° C., 40° C. to 50° C., 40° ° C. to 60° C., 40° C. to 70° C., 40° C. to 80° C., 40° C. to 90° C., 40° C. to 100° C., 50° C. to 60° C., 50° C. to 70° C., 50° C. to 80° C., 50° C. to 90° C., 50° C. to 100° C., 60° C. to 70° C., 60° C. to 80° C., 60° ° C. to 90° C., 60° C. to 100° C., 70° C. to 80° ° C., 70° C. to 90° ° C., 70° C. to 100° C., 80° C. to 90° C., 80° C. to 100° C., or 90° C. to 100° C. The flow rate of the first liquid may be controlled or regulated to maintain a temperature difference between the first liquid and the heat source of greater than or equal to about 1° C., 2° C., 4° C., 6° C., 8° C., 10° C., 12° C., 15° C., 20° C., 25° C., 30° C., 40° C., 50° C., or more. The flow rate of the first liquid may be controlled or regulated to maintain a temperature difference between the first liquid and the heat source of less than or equal to about 50° C., 40° C., 30° C., 25° C., 20° C., 15° C., 12° C., 10° C., 8° C., 6° C., 4° C., 2° C., 1° C., or less. In an example, the method further includes using a refrigeration cycle to maintain the fluid temperature below the ambient temperature (e.g., lower than approximately 20° C.).

The container may include a lid. The lid may comprise a solid material (e.g., metal, plastic, wood, etc.). Alternatively, or in addition to, the lid may comprise a liquid, such as a non-volatile liquid. The lid may be as described elsewhere herein. The method may further include inserting the heat source into the container, adding the first liquid, and applying the lid to the container. The lid may seal the container during cooling. The lid may be sealed by one or more fasteners. Alternatively, or in addition to, the lid may be sealed by welding or otherwise adhering the lid to the container. The container may further include a liner. The liner may be a rigid liner or a deformable liner. The container may further include one or more relief valves or pressure regulators. A relief valve or pressure regulator may be configured to maintain or may maintain a pressure in the container below a threshold value or within a given pressure range. A relief valve or pressure regulator may be disposed in the lid, in a wall of the container, on the bottom of the container, or any combination thereof. In an example, the system includes one or more relief valves. In another example, the system includes one or more pressure regulators. In another example, the system includes both a relief valve and pressure regulator. A relief valve may be coupled to or fluidically connected to a secondary expansion tank. Alternatively, a relief valve is open to an atmosphere external to the tank. The relief valve or pressure relief valve may be configured to prevent or may prevent over pressure of the container. The relief valve may maintain a pressure within the container (e.g., maintain a headspace pressure or fluid pressure) below a threshold value. The threshold value may be less than or equal to 5 bar, 4 bar, 3 bar, 2 bar, 1 bar, 0.9 bar, 0.8 bar, 0.7 bar, 0.6 bar, 0.5 bar, or less. The pressure regulator may maintain the pressure within a given pressure range. The pressure regulator may maintain a pressure from about 0.5 bar to about 0.6 bar, 0.5 bar to about 0.7 bar, 0.5 bar to about 0.8 bar, 0.5 bar to about 0.9 bar, 0.5 bar to about 1 bar, 0.5 bar to about 2 bar, 0.5 bar to about 3 bar, 0.5 bar to about 4 bar, 0.5 bar to about 5 bar, 0.6 bar to about 0.7 bar, 0.6 bar to about 0.8 bar, 0.6 bar to about 0.9 bar, 0.6 bar to about 1 bar, 0.6 bar to about 2 bar, 0.6 bar to about 3 bar, 0.6 bar to about 4 bar, 0.6 bar to about 5 bar, 0.7 bar to about 0.8 bar, 0.7 bar to about 0.9 bar, 0.7 bar to about 1 bar, 0.7 bar to about 2 bar, 0.7 bar to about 3 bar, 0.7 bar to about 4 bar, 0.7 bar to about 5 bar, 0.8 bar to about 0.9 bar, 0.8 bar to about 1 bar, 0.8 bar to about 2 bar, 0.8 bar to about 3 bar, 0.8 bar to about 4 bar, 0.8 bar to about 5 bar, 0.9 bar to about 1 bar, 0.9 bar to about 2 bar, 0.9 bar to about 3 bar, 0.9 bar to about 4 bar, 0.9 bar to about 5 bar, 1 bar to about 2 bar, 1 bar to about 3 bar, 1 bar to about 4 bar, 1 bar to about 5 bar, 2 bar to about 3 bar, 2 bar to about 4 bar, 2 bar to about 5 bar, 3 bar to about 4 bar, 3 bar to about 5 bar, of 4 bar to 5 bar. In an example, the pressure regulator maintains the pressure from about 0.9 bar to 1.1 bar.

The method may further comprise using one or more processors to control one or more aspects of the method or system. The one or more processors may be coupled to the heat exchanger pump. The one or more processors may be used to direct the pump to control a flow of the second liquid through the heat exchanger. The one or more processors may be coupled to the recirculation loop. The one or more processors may be coupled to the pump of the recirculation loop. The one or more processors may direct the pump to control flow of the first liquid through the converging structure of the static suction pump.

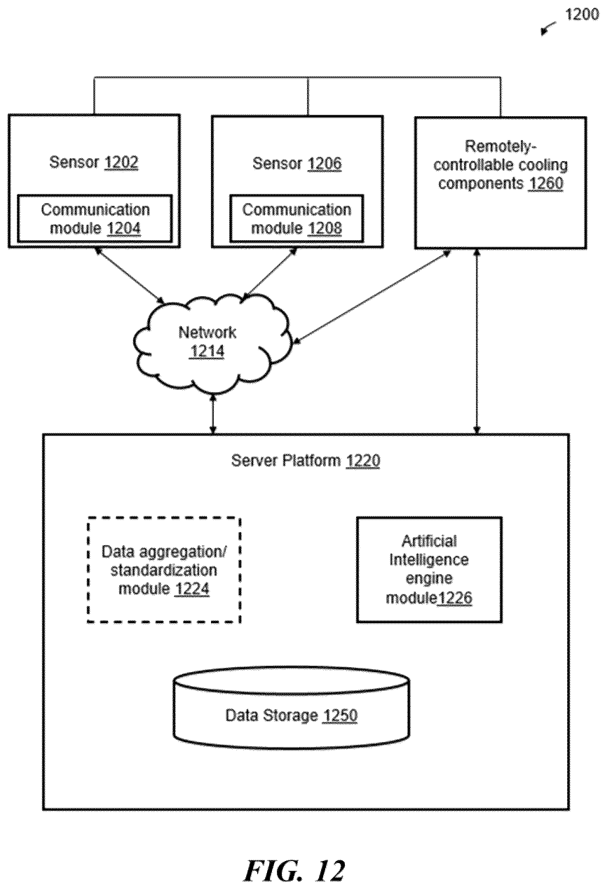

FIG. 12 illustrates a block diagram depicting an example system 1200 comprising a client-server architecture and network configured to perform the various methods described herein. A platform (e.g., hardware and software, possibly interoperating via a series of network connections, protocols, application-level interfaces, and so on), in the form of a server platform 1220, provides server-side functionality via a communication network 1214 (e.g., the Internet or other types of wide-area networks (WANs), such as wireless networks or private networks with additional security appropriate to data transmitted) to one or more sensors 1202 and 1206.

FIG. 12 illustrates, for example, a sensor 1202 that comprises or is operably couple to a communication module 1204, thus allowing the sensor 1202 to transmit data to the server platform 1220, and/or receive commends from the server platform 1220. In some embodiments, the sensor 1202 may be an electrical characteristics sensor, which can be configured to detect one or more specific parameters, such as voltage, electric current, electrical resistance, electrical reactance, electrical charge, partial discharge, electrical power, magnetic flux, magnetic field, etc. Various types of sensors may be utilized to measure the electrical characteristics of different components in an electrical network and its associated components, for example, electricity meter, electrometer, Hall effect sensor, etc. The components associated with the electrical network may comprise, but are not limited to, central processing units (CPUs), graphics processing units (GPUs), circuit boards, chipsets, memory drivers, batteries, or any combination thereof. Electronic components may be used for any application, including, but not limited to, data storage, computer processing, electronic currency mining, or any combination thereof. In an example, the heat source includes a plurality of computer servers.

In some embodiments, the sensor 1202 may be a level sensor, which can be configured to monitor and measure liquid levels. For example, a level sensor 1202 may monitor and measure the liquid levels of the first liquid 104, second liquid hold by the container 103 as shown in FIG. 1. Various types of sensors may be utilized to measure the liquid levels, such as point level sensors, continuous level sensors, and the like. Point level sensors may provide measurements indicative of whether the liquid 104 has reached a specific point in the container 103. Continuous level sensors may provide measurements indicative of precise liquid level measurements. In some embodiments, the level sensor 1202 may comprise invasive and non-contact level sensors. Invasive sensors make direct contact with the liquid being measuring, while non-contact sensors may utilize sound or microwaves to provide measurements.

In some embodiments, the sensor 1202 may be a pressure sensor, which can be configured to monitor and measure pressure of gases and liquids. For example, as described elsewhere herein, the container 103 comprises one or more relief valves or pressure regulators. To regulate the pressure of the container 103, a pressure sensor 1202 may be utilized to provide a measurement of the current pressure in the container 103. Various types of sensors may be utilized to measure the pressures, such as absolute pressure sensor, gauge pressure sensor, vacuum pressure sensor, differential pressure sensor, sealed pressure sensor, and the like.

In some embodiments, the sensor 1202 may be a flow rate sensor, which can be configured to monitor and measure a flow rate of the liquid. For example, as described elsewhere herein, a recirculation loop may include a variable speed pump (e.g., Pump 108 as shown in FIG. 1) to provide an adjustable flow rate. To provide accurate control of the flow rate by variable speed pump, a flow rate sensor 1202 may be utilized to provide a measure of the current flow rate of the liquid. Various types of sensors may be utilized to measure the flow rate, such as piston meter/rotary piston, oval gear meter, gear meter, helical gear, nutating disk meter, turbine flowmeter, Woltman meter, single jet meter, paddle wheel meter, multiple jet meter, venturi meter, laminar flowmeters, variable-area flowmeters, optical flowmeters, open-channel flow measurement, acoustic doppler velocimetry, thermal mass flowmeters, the MAF sensor, vortex flowmeters, magnetic flowmeters, and the like.

Further, FIG. 12 illustrates, for example, another sensor 1206 that comprises or is operably coupled to a communication module 1208, thus allowing the sensor 1206 to transmit data to the server platform 1220, and/or to receive commands from the server platform 1220. The sensor 1206 may be a temperature sensor, which can be configured to measure a temperature of an electrical component, and/or a temperature at a location adjacent to an electrical component. In some embodiments, the temperatures sensors may measure the temperature gradient of an electrical component, and/or at a location adjacent to an electrical component. Various types of temperature sensors may be utilized to measure the temperate in an electrical network, for example, temperature meters, infrared thermometer, thermocouples, mercury-in-glass thermometer, and the like. By continuously monitoring temperature in an electrical network, the system 1200 provides real-time thermal data and can make more accurate measurements as to a current or upcoming electrical condition to facilitate downstream operations. It should be recognized that these examples of sensors 1202, 1206 are presented merely as examples; other types of sensors may be utilized.

The term “real-time,” as used herein, generally refers to a simultaneous or substantially simultaneous occurrence of a first event or action with respect to an occurrence of a second event or action. A real-time action or event may be performed within a response time of less than one or more of the following: ten seconds, five seconds, one second, a tenth of a second, a hundredth of a second, a millisecond, or less relative to at least another event or action. A real-time action may be performed by one or more computer processors. Real-time, as used herein, generally refers to a response time that does not appear to be of substantial delay to a user as graphical elements are pushed to the user via a user interface. In some embodiments, a response time may be associated with processing of data, such as by a computer processor, and may be less than 2 seconds, 1 second, tenth of a second, hundredth of a second, a millisecond, or less. Real-time can also refer to a simultaneous or substantially simultaneous occurrence of a first event with respect to occurrence of a second event.

In at least some examples, the server platform 1220 may be one or more computing devices or systems, storage devices, and other components that include, or facilitate the operation of, various execution modules depicted in FIG. 12. These modules may include, for example, data aggregation/standardization module 1224, Artificial Intelligence (AI) engine 1226, and data storage 1250. Each of these modules is described in greater detail below. The server platform 1220 can facilitate remote processing of sensor data received, which can improve the overall efficiency of the system 1200.

In some embodiments, the server platform 1220 may facilitate data processing in parallel using multi-core processors. Cloud computation mechanism may also be utilized to process sensors data received.

The data aggregation/standardization module 1224 may aggregate sensor data received from the sensors 1202 and 1206. Additionally or alternatively, the data aggregation/standardization module 1224 may standardize the sensor data received from the sensors 1202 and 1206. The data aggregation/standardization module 1224 is only deployed when the received sensor data is in the bespoke format and needed to be normalized. In these cases, the data aggregation/standardization module 1224 can be configured to transform the received sensor data from a source format to a target format. For example, the fingerprint of a temperature sensor O indicates the data format is in Celsius and Swiss date format, thus the temperature data of sensor O is 27° C. at (dd.mm.yyyy). Another temperature sensor P's fingerprint indicates the data format is in Fahrenheit and U.S. date format, thus the temperature data of sensor P is 80.6° F. at (mm.dd.yyyy). The data aggregation/standardization module 1224 may obtain the fingerprints of both temperature sensors, and transform them in an ontology that has a data format of Celsius and National date format (i.e., YYYY-MM-DD). By transforming the two sets of data into the Celsius and National date format, the data aggregation/standardization module 1224 may generate data set that can provide better visibility and actionable insight, as well as provide a uniform data set for the downstream operations. In some embodiments, the data aggregation/standardization module 1224 optionally comprises Machine Learning (ML) model to normalize the sensor data. The ML model is trained from historical training examples showing the formatting mechanism from source data format to target data format. Example ML models include, by way of examples, regular or deep neural networks, support vector machines, Bayesian models, linear regression, logistic regression, k-means clustering, or the like.

The data aggregation/standardization module 1224 may store the sensor data to the data storage 1250. Examples of the data storage 1250 include, but are not limited to, one or more data storage components, such as magnetic disk drives, optical disk drives, solid state disk (SSD) drives, and other forms of nonvolatile and volatile memory components. The data storage 1250 may deploy a relational database mechanism. Additionally or alternatively, the data storage 1250 may deploy a combination of relational database and a time-series database mechanism. A time-series database may reflect the data changes of the sensor data overtime. A relational database may have the benefit of robust secondary index support, complex predicates, a rich query language, etc. However, when the data changes rapidly overtime, the volume of data can scale up enormously. Thus, having a separate time-series database that works alongside the relational database may improve scalability.

In another embodiment, the data storage 1250 utilizes a graph database to store the sensor data. A graph database is a database that uses graph structure for semantic queries with nodes (please note that “node” and “vertex” are used interchangeably in this application), edges, and properties to represent and store data. The data storage component of the present application provides a data structure wherein each vertex (node) in the graph also has a time-series store to capture data change overtime. The time-series store may be a standalone database, or it can be defined as a property of the vertex (node). For example, the temperature data extracted from temperature sensor O at 8 pm on Jan. 27, 2022 may be stored in a graph database. The node in the graph may represent sensor O and the value is 27° ° C. The timestamp 8 pm on Jan. 27, 2022 is stored as property for this node in the graph of the graph database. The time-series store may be associated with the nodes, and it may reflect the data changes overtime and provide a user with actionable insight. The relationships between different nodes are stored by edges. For example, the relationship between the measurement of temperature sensor O associated with an electrical panel A and the measurement of the voltage meter of same electrical panel A may be defined by the edge between them. As describe above, because the sensor data is stored with time-series stored in a database, the resulting data contains a dynamic representation of the electrical network monitored rather than a static view. In the subsequent operations, the evolved and evolving vertices (nodes) in the graph may provide both provenance and history associated with them, and thus enable the Artificial Intelligence (AI) engine 1226 to simulate the electrical networks monitored and provide predictions of electrical fault conditions.

The Artificial Intelligence (AI) engine 1226 may be communicatively coupled with the data storage 1250. In some embodiments, a plurality of AI engines (e.g., customer AI engine, advisor AI engine, product AI engine) may act in parallel, which consistently act and react to other engine's action at any given time and/or over time, which actions may be based on detected, inter-relational dynamics as well as other factors leading to more effective actionable value. In some embodiments, the one or more AI engines may be deployed using a cloud-computing resource which can be a physical or virtual computing resource (e.g., virtual machine). In some embodiments, the cloud-computing resource can be a storage resource (e.g., Storage Area Network (SAN), Network File System (NFS), or Amazon S3™), a network resource (e.g., firewall, load-balancer, or proxy server), an internal private resource, an external private resource, a secure public resource, an infrastructure-as-a-service (IaaS) resource, a platform-as-a-service (PaaS) resource, or a software-as-a-service (SaaS) resource. Hence, in some embodiments, a cloud-computing service provided can comprise an IaaS, PaaS, or SaaS provided by private or commercial (e.g., public) cloud service providers.

The AI engine 1226 may query the data storage 1250 for historical sensor data and train a Machine Learning (ML) model (or other predictive models). The ML model may generate an output indicative of actions needed to maintain the desired temperature for electrical components and the system.

In some embodiments, the ML model may query the data storage 1250 for historical blueprint data or sensor data to generate a digital twin for the computational systems and the associated cooling systems. A digital twin is a virtual representation that serves as the real-time digital counterpart of a physical object or process. For example, a digital twin for the computational systems and the associated cooling systems may be a virtual representation of the topological relationships between each electrical components, a heat source (e.g., computer server), a baffle (the baffle 102 in FIG. 1), a container (e.g., container 103 in FIG. 1), a liquid (e.g., the first liquid 104 in FIG. 1), heat generating components (e.g., the heat generating components 105 in FIG. 1), open bottom or a bottom plate (e.g., open bottom or a bottom plate 106 in FIG. 1), a converging structure (e.g., the converging structure 107 in FIG. 1), a pump (e.g., a pump 108 in FIG. 1), a recirculation loop (e.g., recirculation loop 109 in FIG. 1), a heat exchanger (e.g., the heat exchanger 110 in FIG. 1), a lid (e.g., the lid 111 in FIG. 1) and the like. The digital twin may provide insight as to what components may provide what amount of cooling effect on what other components in a given time period, at a given flow rate, etc. The digital twin may also predict temperature associated with a certain electrical component(s) if the liquid is direct to flow at a given flow rate.

The ML model may provide predictions indicative of a future temperature change, and may be utilized to take measures proactively. For example, as described elsewhere herein, the electrical components (e.g., central processing units (CPUs), graphics processing units (GPUs), circuit boards, chipsets, memory drivers, batteries, or the like) may be associated with temperature limits, i.e., the electrical components are designed to operate at a specified temperature range, with upper limits, and sometime lower limits. When operating outside of the temperature range, it may cause shortening the lifespan or failures of the electrical components. The ML model may predict a future temperature change and may alter a user when the temperature falls outside of the temperature limits of the electrical components.

In some embodiments, the ML model may predict a potential overheat event based on the real-time thermal signals received from one or more sensors 1206. By continuously measuring and monitoring the temperature associated with the electrical components, the system 1200 provides a set of data that may be utilized by the AI engine 1226 to predict the probability and remaining time to take an action, thereby facilitate corrective actions. In this case, the ML model may be pre-trained by labeled training examples such as a set of thermal measurements and the labeled results (e.g., overhear/not overheat). The ML model may generate an output indicative of whether there is/will be an overhear event associated with an electrical component. This output is a binary output. In some embodiments, the ML model may generate an output comprising a probability distribution over a plurality of levels and imminency of an overheat event. This output is a multi-class output. For example, the output may indicate a probability of a component A will incur an overhear event is 75%, and/or it may happen in 3 days.

In some embodiments, the ML model may be pre-trained by a set of labeled training examples that take into consideration thermal measurements, electrical characteristic measurements, levels sensors data, pressure sensor data, flow rate sensor data stored in data storage 1250. In this case, the thermal data, the electrical characteristic data, the levels sensors data, the pressure sensor data, the flow rate sensor and the interplay between the data are utilized to train the ML model. As described elsewhere herein, the graph database provides a data structure that captures data changes overtime, and the relationships and interplays (captured by the edges of a graph database) between the data from different sensors. This data structure may further the training process for a ML model, and thereby provide predictions of overhear events.

Once trained, the ML model may generate an output indicative of an upcoming overheat event based on real-time thermal measurements and/or electrical characteristic measurements, levels sensors data, pressure sensor data, flow rate sensor data and the like. In some embodiments, an example of the output is: because the temperature of an electrical component A is 76 F, component A is going to experience an overheat event soon (i.e., over 80 F, which is the upper limit of the temperature limit for component A). This example shows an output that is indicative of an upcoming overhear event based on real-time thermal measurement. Another example of the output is: because the temperature of an electrical component A is 76 F, and the liquid flow rate of the liquid cooling component A is regulated at 80 F, component A will experience an overheat event to be over 80 F. This example shows an output that is indicative of an upcoming overheat event based on real-time thermal measurement and real-time liquid flow rate.

Yet another example of the output is: because the temperature of an electrical component A is 76° F., the voltage of component A is 200 volt (i.e., component A is generating heat quickly), and the liquid flow rate of the liquid cooling component A is regulated at 80° F., component A will experience an overheat event. This example shows an output that is indicative of an upcoming overheat event based on real-time thermal measurement, electrical characteristic measurement, and real-time liquid flow rate.

Another example of the output is: because the temperature of an electrical component A is 76 F, and the voltage of component A is 200 volt (i.e., component A is generating heat quickly), component A will experience an overheat event in 5 days. This example shows an output that is indicative of an upcoming overheat event and the imminency of the upcoming overheat event based on real-time thermal measurement and electrical characteristic measurement. Yet another example of the output is: because the temperature of component A is 76 F, and the voltage of component A is 200 volt, there is a 75% chance that component A will experience an overheat event. This example shows an output that is indicative of an upcoming overheat event and the probability of the upcoming overheat event. In some embodiments, the output is: because the temperature of component A is 75 F, and the voltage of component A is 200 volt, there is a 75% chance that component A will experience an overheat event in 5 days. This output is indicative of an upcoming overheat event and the probability and imminency of the upcoming overheat event.

In some embodiments, with the aid of the digital twin, corollary data that is indicative of spatial and/or geographical adjacency between electrical components and other components of the cooling systems may also be utilized to train the ML model. In other words, the topological relationships of an electrical networks and the associated cooling systems are utilized to the train the ML model, as well as the continuously-measured thermal indicators, the electrical characteristic measurement, the levels sensors data, the pressure sensor data, the flow rate sensor data and the like. The spatial and/or geographical adjacency between electrical components and other components of the cooling systems comprises a distance between two components less than 0.9, 0.8, 0.7, 0.6, 0.5, 0.4, 0.3, 0.2, 0.1, 0.09, 0.08, 0.07, 0.06, 0.05, 0.04, 0.03, 0.02, 0.01, 0.009, 0.008, 0.007, 0.006, 0.005, 0.004, 0.003, 0.002, or 0.001 meters.

In some cases, the spatial and/or geographical adjacency between electrical components and other components of the cooling systems comprises a distance between two components less than 0.9, 0.8, 0.7, 0.6, 0.5, 0.4, 0.3, 0.2, 0.1, 0.09, 0.08, 0.07, 0.06, 0.05, 0.04, 0.03, 0.02, or 0.01 centimeters. In some cases, the spatial and/or geographical adjacency between electrical components and other components of the cooling systems comprises the two components locate in the same building, the same campus, the same cluster of buildings. In some cases, the spatial and/or geographical adjacency between electrical components and other components of the cooling systems comprises the two components locate in the same city, the same county, etc.

As described elsewhere herein, individual electrical component on the same electrical network affects each other's status because of the electric current run pass them, the heat they generated, the magnetized effects of some components, vibration and noise they generated, etc. Therefore, the topological relationships between different electrical components provide yet another set of data for training dataset.

For example, in terms of geographically adjacency, the ML model may be trained to understand that a temperature increase in area S may be caused by a turn-on event associated with a HVAC in area S, and it should have limited significance as to the electrical health associated with component B (which also located in area S). In another example, in terms of connectively adjacency, the ML model may be trained to understand that: in a scenario where component P and component Q are electrically coupled with each other, an electric current spark induced by component P to component Q should have limited significance as to component Q's electrical health. Once trained, the ML model may generate an output that is not only indicative of an upcoming overheat event based on real-time thermal measurements and/or electrical characteristic measurements, but also indicative of the effects that this upcoming overheat event may have on other electrical components that are either connectively or geographically adjacent to the electrical component experiencing an overheat event. In some embodiments, the ML model may train itself when the AI engine 1226 is in idle or in low demand, i.e., the incoming real-time sensor data is received at a low data rate. The ML model may identify patterns by query random nodes and discovery the underlying relationships from the stored data from data storage 1250.

In some embodiments, the output of the ML model may be presented to an end user via a User Interface (UI) (not shown in FIG. 12). A maintenance team may utilize this output to take other corrective actions. Alternatively or additionally, the relationships between sensors and monitored electrical components may be visualized and shown on the UI. In another embodiment, the up-and-running duration of an electrical network, overall health of an electrical network, and the next recommended maintenance, etc. may be shown on the UI. In yet another embodiment, the system 1200 may make further recommendations, based on the output of the predictive model (e.g., ML model as described elsewhere herein), regarding what corrective actions to take to ensure the healthiness and safety of the electrical network.

In some embodiments, the ML model may generate a set of commands that provide corrective actions and send to remotely-controllable cooling components 1260. As depicted in FIG. 12, the remotely-controllable cooling components 1260 may be coupled directly to the server platform 1220, thus circumventing the network 1214. For example, the remotely-controllable cooling components 1260 may be co-located with the server platform 1220, coupled thereto via a local network interface. In another example, the remotely-controllable cooling components 1260 may communicate with the server platform 1220 via a private or public network system, such as the network 1214.

In some embodiments, the remotely-controllable cooling components 1260 may directly couple to sensors 1202 and 1206, wherein the remotely-controllable cooling components 1260 may obtain sensor data directly from sensors 1202 and 1206. In some embodiments, sensors 1202 and 1206 may comprise sensors that are embedded with one or more electrical components (e.g., CPU, GPU, circuit boards, chipsets, memory drivers, batteries, etc.), and provide measurements to the remotely-controllable cooling components 1260 directly, thereby bypass the server platform 1220.

The remotely-controllable cooling components 1260 may comprise a heat source (e.g., computer server), a baffle (the baffle 102 in FIG. 1), a container (e.g., container 103 in FIG. 1), a liquid (e.g., the first liquid 104 in FIG. 1), heat generating components (e.g., the heat generating components 105 in FIG. 1), open bottom or a bottom plate (e.g., open bottom or a bottom plate 106 in FIG. 1), a converging structure (e.g., the converging structure 107 in FIG. 1), a pump (e.g., a pump 108 in FIG. 1), a recirculation loop (e.g., recirculation loop 109 in FIG. 1), a heat exchanger (e.g., the heat exchanger 110 in FIG. 1), a lid (e.g., the lid 111 in FIG. 1) and the like. These remotely-controllable cooling components 1260 may be turned on/off remotely by commands without human intervention. In some embodiments, parameters associated with remotely-controllable cooling components 1260 may be adjusted by commands without human intervention, such as adjusting a pump speed of the pump 108 as shown in FIG. 1, adjusting an air blowing speed of the blower 301 as shown in FIG. 3, and the like.

In some embodiments, the AI engine 1226 may query the data storage 1250 for the digital twin for the computational systems and the cooling systems, historical sensor, and retrieve/receive the real-time sensor data to provide predictions of upcoming overheat events, as described elsewhere herein. The ML model is trained to provide predictions of upcoming overheat events for one more electrical components, as described elsewhere herein. In some embodiments, these predictions may be fed back to the ML model to generate recommendations for correction actions. In some other embodiments, these predictions may be fed back to the ML model to generate commands that control the remotely-controllable cooling components 1260 to take corrective actions. For example, the ML model may be trained to send commands to increase the liquid flow rate near an electrical component A if there is a prediction output indicating component A will experience an overheat event soon. Corrective actions may comprise, without limitation, increase a liquid flow rate, decrease a liquid temperature, enable a two-phase cooling mode (as shown by reference with FIG. 10), direct or redirect a liquid flow by recirculation loop outlet 1106, and the like. By utilizing preset rules (e.g., best practice guidelines), digital twin or other simulation of the systems, historical sensor data, the ML model may be trained to generate these commands automatically without human intervention.

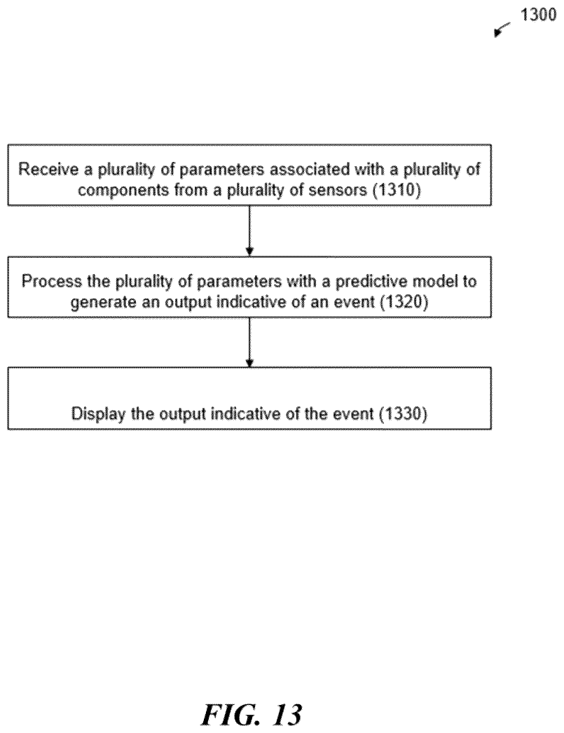

FIG. 13 illustrates a flow diagram depicting an example process 1300 for intelligently cooling a computational system, according to one embodiment. As depicted in FIG. 13, once the platform and systems of the present disclosure is initialized, the process 1300 begins with operation 1310, wherein the system 1200 receives and collects parameters associated with one or more components from one or more sensors. The parameters may comprise, without limitation, thermal measurements, electrical characteristic measurements, levels sensors data, pressure sensor data, flow rate sensor data, and the like. Next, the process 1300 may proceed to operation 1320, wherein the system 1200 may process the received parameters with a predictive model (e.g., ML model as described elsewhere herein), to generate an output indicative of an event. The event may comprise, without limitation, an overheat event, an early failure event, and the like associated with an electrical component. Next, the process 1300 may continue to operation 1330, wherein the system 1200 may display the output indicative of the event. In some embodiments, the output may be presented to a user via a User Interface (UI).

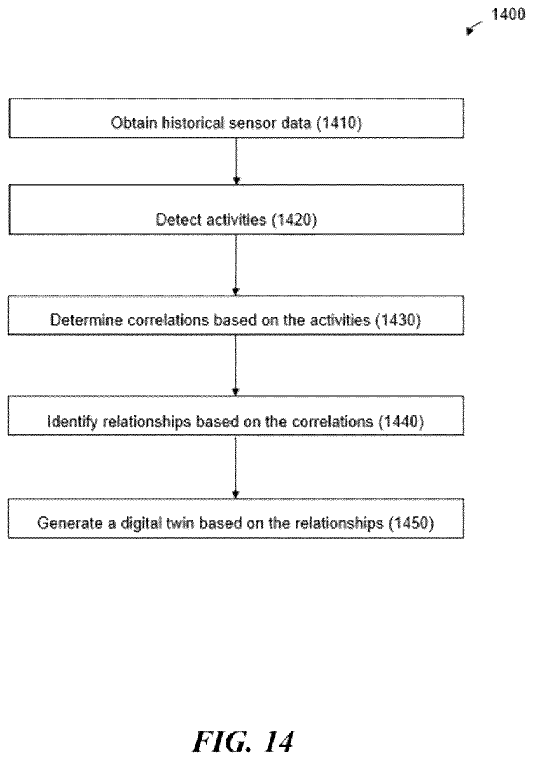

FIG. 14 illustrates a flow diagram depicting an example process 1400 for intelligently cooling a computational system, according to one embodiment. As depicted in FIG. 14, once the platform and systems of the present disclosure is initialized, the process 1400 begins with operation 1410, wherein the system 1200 may obtain historical sensor data. In some embodiments, the AI engine 1226 may query the data storage 1250 for historical sensor data. Next, the process 1400 may proceed to operation 1420, wherein the system 1200 may detect activities by parsing and analyzing the historical sensor data. Activities may comprise, without limitation, a temperature rise associated with a component A at a given time point, a liquid flow rate decrease near a component B at a given time point, etc. In some embodiments, the system 1200 may detect these changes on parameters and mark them as activities. Next, the process 1400 may proceed to operation 1430, wherein the system may determine correlations between different components based on the activities. In some embodiments, a Machine Learning (ML) model (or other predictive models) may be utilized to determine the correlations between different components. In some embodiments, the system 1200 will quest the activities occurred at the same time, or during a short time window, to determine whether there is a correlation between two or more components. For example, if component A's temperature increased at time O by 4 degrees, and a liquid flow rate decreased at the same time point time O, there may be a correlation between the component A's temperature and the liquid flow rate. The ML model may be trained to recognize these correlations. Next, the process 1400 may proceed to operation 1440, wherein the system 1200 may identify relationships between different components based on the correlations. This may be accomplished by determine the correlations across different time points. For example, if every time when the liquid flow rate decrease, there is a rise on component A's temperature read, then the system 1200 may identify there is a relationship between component A and the pump controlling the liquid flow rate. Next, the process 1400 may proceed to operation 1450, wherein the system 1200 may generate a digital twin based on the relationships. For example, the system 1200 may aggregate the relationships into a virtual representation between different components. A graph database may be utilized to store this digital twin, wherein each component may be represented by “node” or “vertex”, and the relationship between two components may represented by the “edge” linking the two nodes representing the two components. In some embodiments, the digital twin may be stored in the data storage 1250.

### Computer Systems

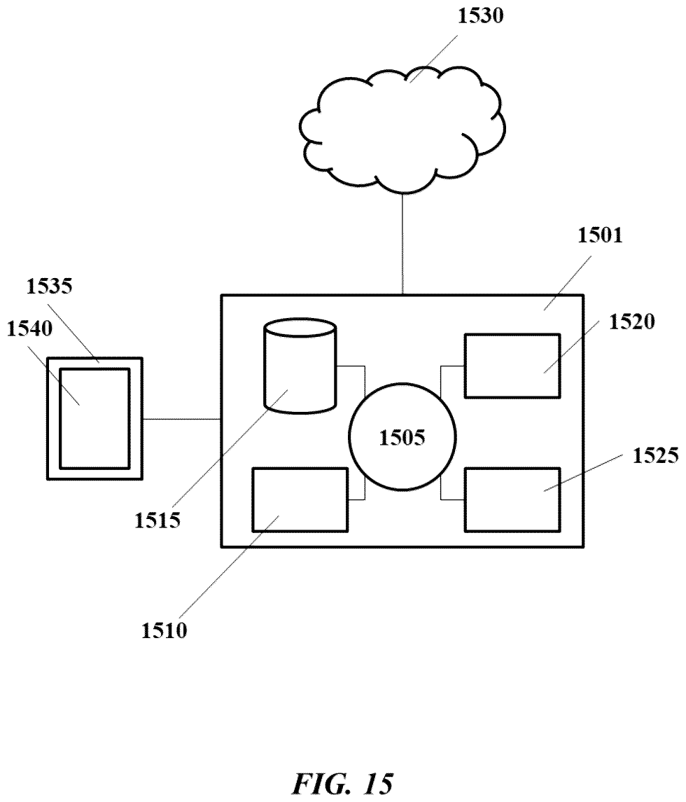

The present disclosure provides computer systems that are programmed to implement methods of the disclosure. FIG. 15 shows a computer system 1501 that is programmed or otherwise configured to implement the methods described elsewhere herein. The computer system 1501 can regulate various aspects of electronics cooling of the present disclosure, such as, for example, maintaining and controlling cooling fluid flow rates, temperature of the heat source, and flow rate of heat exchanging fluid. The computer system 1501 can be an electronic device of a user or a computer system that is remotely located with respect to the electronic device. The electronic device can be a mobile electronic device.

The computer system 1501 includes a central processing unit (CPU, also “processor” and “computer processor” herein) 1505, which can be a single core or multi core processor, or a plurality of processors for parallel processing. The computer system 1501 also includes memory or memory location 1510 (e.g., random-access memory, read-only memory, flash memory), electronic storage unit 1515 (e.g., hard disk), communication interface 1520 (e.g., network adapter) for communicating with one or more other systems, and peripheral devices 1525, such as cache, other memory, data storage and/or electronic display adapters. The memory 1510, storage unit 1515, interface 1520 and peripheral devices 1525 are in communication with the CPU 1505 through a communication bus (solid lines), such as a motherboard. The storage unit 1515 can be a data storage unit (or data repository) for storing data. The computer system 1501 can be operatively coupled to a computer network (“network”) 1530 with the aid of the communication interface 1520. The network 1530 can be the Internet, an internet and/or extranet, or an intranet and/or extranet that is in communication with the Internet. The network 1530 in some cases is a telecommunication and/or data network. The network 1530 can include one or more computer servers, which can enable distributed computing, such as cloud computing. The network 1530, in some cases with the aid of the computer system 1501, can implement a peer-to-peer network, which may enable devices coupled to the computer system 1501 to behave as a client or a server.

The CPU 1505 can execute a sequence of machine-readable instructions, which can be embodied in a program or software. The instructions may be stored in a memory location, such as the memory 1510. The instructions can be directed to the CPU 1505, which can subsequently program or otherwise configure the CPU 1505 to implement methods of the present disclosure. Examples of operations performed by the CPU 1505 can include fetch, decode, execute, and writeback.

The CPU 1505 can be part of a circuit, such as an integrated circuit. One or more other components of the system 1501 can be included in the circuit. In some cases, the circuit is an application specific integrated circuit (ASIC).

The storage unit 1515 can store files, such as drivers, libraries and saved programs. The storage unit 1515 can store user data, e.g., user preferences and user programs. The computer system 1501 in some cases can include one or more additional data storage units that are external to the computer system 1501, such as located on a remote server that is in communication with the computer system 1501 through an intranet or the Internet.

The computer system 1501 can communicate with one or more remote computer systems through the network 1530. For instance, the computer system 1501 can communicate with a remote computer system of a user (e.g., cellular phone, laptop, tablet, desktop, or any combination thereof). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 1501 via the network 1530.

Methods as described herein can be implemented by way of machine (e.g., computer processor) executable code stored on an electronic storage location of the computer system 1501, such as, for example, on the memory 1510 or electronic storage unit 1515. The machine executable or machine readable code can be provided in the form of software. During use, the code can be executed by the processor 1505. In some cases, the code can be retrieved from the storage unit 1215 and stored on the memory 1510 for ready access by the processor 1505. In some situations, the electronic storage unit 1515 can be precluded, and machine-executable instructions are stored on memory 1510.

The code can be pre-compiled and configured for use with a machine having a processor adapted to execute the code or can be compiled during runtime. The code can be supplied in a programming language that can be selected to enable the code to execute in a pre-compiled or as-compiled fashion.

Aspects of the systems and methods provided herein, such as the computer system 1501, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 1501 can include or be in communication with an electronic display 1535 that comprises a user interface (UI) 1540 for providing, for example, status of the cooling system, fluid flow rates, system temperature, or any combination thereof. Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 1505. The algorithm can, for example, direct the system to maintain a temperature of the heat generating component, regulate flow of the recirculation pump, regulate flow through the heat exchangers, or any combination thereof.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1.-79. (canceled)

80. A method for cooling a heat source, comprising:
a. providing a cooling system in thermal communication with said heat source, wherein said cooling system comprises (i) a container comprising a container wall, wherein said container comprises said heat source submerged in a first liquid, (ii) a baffle disposed between said heat source and said container wall, and (iii) a recirculation loop comprising (A) a passageway comprising a converging structure disposed between said baffle and said container wall and (B) a pump that directs the flow of said first liquid through said converging structure, wherein said first liquid is in thermal communication with said heat source;
b. transferring thermal energy from said heat source to said first liquid and, during said transferring, using said baffles to direct flow of said first liquid away from said heat source; and
c. using said pump of said recirculation loop to direct said first liquid through said converging structure of said passageway to generate a suction force that pulls said first liquid through said converging structure and generates flow of said first liquid between said baffle and said container wall to thereby cool said heat source.

81. The method of claim 80, further comprising flowing said first liquid such that said first liquid is maintained in a subcooled state.

82. The method of claim 81, wherein said baffle directs said first liquid towards said container wall.

83. The method of claim 82, wherein said first liquid is a dielectric liquid.

84-86. (canceled)

87. The method of claim 80, wherein said baffle comprises a bottom plate comprising perforations that permit flow of said first liquid through said bottom plate.

88. (canceled)

89. The method of claim 88, wherein said baffle comprises a flow diverter that directs flow of said first liquid around said heat source.

90. The method of claim 89, wherein said container comprises a lid that seals said container.

91. The method of claim 90, wherein said container comprises a liquid lid disposed adjacent to and above said first liquid.

92. The method of claim 91, wherein said container comprises a float that displaces a volume of said liquid lid.

93. The method of claim 92, wherein said container comprises a relief valve that maintains a pressure of said container below a threshold value.

94. The method of claim 93, wherein said container comprises a liner configured to seal said first liquid inside said container.

95.-96. (canceled)

97. The method of claim 80 further comprising using one or more processors coupled to said pump to control a flow of said first liquid through said converging structure.

98.-99. (canceled)

100. The method of claim 80, wherein said heat source is a mining machine, and wherein said mining machine comprises a wireless handle.

101. The method of claim 100, wherein said wireless handle comprises a wireless emitter.

102. A method for predicting an overheating event to aid in cooling a heat source, comprising:
(a) receiving a plurality of parameters associated with a plurality of electrical components of an electrical network from a plurality of sensors, wherein one of said plurality of sensors is a temperature sensor; and
(b) computer processing said plurality of parameters with a predictive model to generate an output indicative of said overheating event, wherein said predictive model is trained on a training dataset comprising a plurality of historical data of said plurality of parameters across different time points, and wherein said plurality of historical data is labeled as originating or not originating from an electrical component that has undergone an overheating event.

103. The method of claim 102, wherein said predictive model is a binary predictive model, and wherein said output is a binary output that indicates whether one of said plurality of electrical components will or will not have said overheat event.

104. The method of claim 103, wherein said predictive model is a multi-class predictive model, and wherein said output comprises a probability distribution over a plurality of levels or imminency of said overheat event.

105. The method of claim 104, wherein said plurality of sensors comprises electrical characteristic sensors.

106. (canceled)

107. The method of claim 102, wherein said training dataset comprises topological relationships between said plurality of electrical components.

108. The method of claim 107, wherein said temperature sensor is an infrared thermometer.
